(19) United States
(12) Patent Application Publication
(10) Pub. No.: US 2010/0054292 A1
(43) Pub. Date: Mar. 4, 2010

(54) SEMICONDUCTOR LASER DEVICE AND MANUFACTURING METHOD THEREOF

(75) Inventor: Yasuyuki BESSHO, Uji City (JP)

Correspondence Address: MOTS LAW PLLC, Suite 602, 1629 K Street, N.W., Washington, DC, 20006, US

(73) Assignee: SANYO ELECTRIC CO., LTD., Osaka (JP)

(21) Appl. No.: 12/546,394

(22) Filed: Aug. 24, 2009

(30) Foreign Application Priority Data
Aug. 26, 2008 (JP) 2008-216186

(51) Int. Cl. H01S 5/026; H01L 21/30

(52) U.S. Cl. 372/49.01; 438/31; 257/E21.211

(57) ABSTRACT

A first semiconductor laser element is formed on a surface of a substrate and has a first cavity facet. The first semiconductor laser element has a first recess in the first cavity facet except for at least a region where a first optical waveguide is formed. The first recess extends in a first direction in which the first cavity facet extends. A second semiconductor laser element is bonded to a first surface of the first semiconductor laser element. The first surface is arranged opposite side of the first laser element to the substrate, and has a second cavity facet formed in substantially the same plane as the first cavity facet. The second semiconductor laser element has a second recess in the second cavity facet except for a region where a second optical waveguide is formed, the second recess extending in a second direction in which the second cavity facet extends.

### CROSS REFERENCE TO RELATED APPLICATIONS

This application claims priority based on 35USC119 from prior Japanese Patent Application No. P2008-216186 filed on Aug. 26, 2008, entitled “SEMICONDUCTOR LASER DEVICE AND MANUFACTURING METHOD THEREOF”, the entire contents of which are incorporated herein by reference.

### BACKGROUND OF THE INVENTION

1. Field of the Invention

The invention relates to a semiconductor laser device and a manufacturing method thereof, and in particular, relates to a semiconductor laser device including integrated semiconductor laser elements and a manufacturing method thereof.

2. Description of Related Art

A conventional semiconductor laser device including optical waveguides is disclosed in, for example, Japanese Patent Application Publication No. 2003-17791 (herein referred to as patent literature 1)

Patent literature 1 discloses a nitride semiconductor laser device including nitride compound semiconductor layers formed on a GaN substrate, and a manufacturing method thereof. A manufacturing process of the nitride semiconductor laser device described in patent literature 1 includes a step of forming scribed grooves (grooves for cleavage) in dashed line shapes along dividing lines of a wafer prior to a step of cleaving the wafer including optical waveguides into bars in order to form cavity facets. Accordingly, when the bar cleavages are formed, the semiconductor layers are cleaved in the direction in which the scribed grooves extend, at the positions where the scribed grooves are formed. It is therefore possible to form cavity facets that have flat cleaved surfaces extending in a desired direction in the nitride semiconductor laser device.

In recent years, for the purposes of miniaturizing optical disk pickup apparatus used for DVD drives and the like and simplifying the structures thereof, there has been developed an optical disk pickup apparatus which includes an integrated multi-wavelength semiconductor laser device. Here, the integrated multi-wavelength semiconductor laser device has multiple semiconductor laser elements integrated into a single chip, the multiple semiconductor laser elements emitting respective laser beams with different wavelengths. Additionally, an example of known multi-wavelength semiconductor laser devices is one which has three semiconductor laser elements of red, infrared and blue-violet semiconductor laser elements integrated into a single chip.

In the case of forming the aforementioned multi-wavelength semiconductor laser device, a wafer having blue-violet semiconductor laser elements formed by laminating nitride compound semiconductors on a GaN substrate is bonded to a wafer having monolithic red/infrared semiconductor laser elements formed by laminating semiconductors made of compounds of Ga, P, and the like on a GaAs substrate. Then, the wafers thus bonded to each other are cleaved to form cavity facets of the respective semiconductor laser elements.

The nitride semiconductor laser device and the manufacturing method thereof disclosed in patent literature 1 are considered to be applicable to formation of the cavity facets in fabrication of a single-wavelength semiconductor laser device emitting a single type of laser light. However, if the nitride semiconductor laser device and the manufacturing method thereof disclosed in patent literature 1 are applied to a method of fabricating an integrated multi-wavelength semiconductor laser device by bonding multiple semiconductor laser elements to each other, the following problem occurs. For example, here consider a case of bonding together and then cleaving two wafers one of which includes blue-violet semiconductor laser elements with the scribed grooves (grooves for cleavage) formed thereon, and the other of which includes monolithic red/infrared semiconductor laser elements with no scribed grooves formed thereon. In this case, the wafers may be cleaved so that the cleaved surfaces formed on the blue-violet semiconductor laser elements may be misaligned in the cavity direction with respect to the cleaved surfaces of the red/infrared semiconductor laser elements. As a result, there is a problem that the cavity facets constituting the three semiconductor elements are misaligned in the cavity direction. In this regard, if the multi-wavelength semiconductor laser device after the cleavage has these three semiconductor laser elements whose cavity facets on the light emitting side are misaligned in the cavity direction, part of laser light from one of the semiconductor laser elements comes into contact with the cleaved surface of another adjacent semiconductor laser element because of a recessed shape formed between the cavity facets. In this case, since the part of laser light is interrupted by the cleaved surface of the adjacent semiconductor laser element, the shape of the beam is abnormal. Accordingly, in the fabrication of multi-wavelength semiconductor laser device, the cavity facets of respective semiconductor laser elements are required to be formed in the same plane.

### SUMMARY OF THE INVENTION

An aspect of the invention provides a semiconductor laser device that comprises a first semiconductor laser element which is formed on a surface of a substrate and has a first cavity facet, the first semiconductor laser element having a first recess in a region of the first cavity facet except for at least a region where a first optical waveguide is formed, the first recess extending in a first direction in which the first cavity facet extends; and a second semiconductor laser element which is bonded to a first surface of the first semiconductor laser element, the first surface being opposite side of the first laser element to the substrate, and has a second cavity facet formed in substantially the same plane as the first cavity facet, the second semiconductor laser element having a second recess in a region of the second cavity facet except for at least a region where a second optical waveguide is formed, the second recess extending in a second direction in which the second cavity facet extends.

The semiconductor laser device according to the first aspect, as described above, includes: the first semiconductor laser element having the first recess extending in the direction in which the first cavity facet extends; and the second semiconductor laser element having the second recess extending in the direction in which the second cavity facet extends, the second cavity facet being formed in substantially the same plane as the first cavity facet. The first and second recesses are therefore formed in substantially the same planes as the first and second cavity facets, respectively. Accordingly, in the manufacturing process thereof, the first cavity facet including a cleavage surface cleaved starting from the first recess of the first semiconductor laser element and the second cavity facet including a cleavage surface cleaved starting from the second recess of the second semiconductor laser element can be aligned in substantially the same plane. In the integrated multi-wavelength semiconductor laser device, it is therefore possible to prevent the cavity facets of the respective semiconductor laser elements from being misaligned in the cavity direction.

In the semiconductor laser device according to the first aspect, preferably, the second recess extends from a second surface of the second semiconductor laser element to a third surface of the second semiconductor laser element, the second surface opposite side of the second laser element to the first semiconductor laser element, the third surface being bonded to the first semiconductor laser element. In such a configuration, the second recess penetrates the semiconductor element layers of the second semiconductor laser element in the thickness direction. This facilitates cleaving the semiconductor element layers in the manufacturing process. Thus, the second cavity facet can be easily formed.

In the configuration in which the second recess extends from the second surface of the second semiconductor laser element to the third surface, preferably, the first recess is formed to extend from the first surface to the substrate so as to be continuous with the second recess extending from the second surface to the third surface. With such a configuration, in the first semiconductor laser element, the first recess is formed so as to be continuous to the second recess penetrating the second semiconductor laser element in the thickness direction. Accordingly, in the manufacturing process, the second recess for forming the second cavity facet and the first recess for forming the first cavity facet can be simultaneously formed in the thickness direction of the semiconductor element layers.

In the semiconductor laser device according to the first aspect, preferably, the first and second recesses are arranged so as to overlap with each other in a plan view. With such a configuration, the planar regions of the first and second recesses overlap with each other in the direction in which the first or second cavity facet extends. Accordingly, in the manufacturing process thereof, the semiconductor element layers are cleaved starting from the first recess and the second recess formed at substantially the same position as the first recess. Thus, the first and second cavity facets can be simultaneously formed.

In the semiconductor laser device according to the first aspect, preferably, the first recess is formed in a vicinity of a first end of the first cavity facet, in the direction, and the second recess is formed in a vicinity of a second end of the second cavity facet, in the second direction, the second end being on the same side where the first recess is formed. With such a configuration, both the first and second semiconductor laser elements include the recesses (first and second recesses) in the vicinity of the ends of the cavity facets on the same side. Accordingly, unlike the case where the recesses are not formed in the vicinity of the ends of the cavity facets, it is possible to prevent the semiconductor element layers from being broken or cracked in the vicinity of the ends of the cavity facets.

The manufacturing method of a semiconductor laser device includes: a step of bonding the second semiconductor laser element to a surface of the first semiconductor laser element opposite side of the substrate; and a step of forming a groove for cleavage in a region of the first and second semiconductor laser elements except for at least a region where the first and second optical waveguides are formed, the grooves for cleavage extending in a direction substantially perpendicular to a direction in which the first and second optical waveguides extend; and a step of performing cleavage along the groove for cleavage so as to form the first semiconductor laser element which has a first recess corresponding to the groove for cleavage, the first recess extending in a direction in which the first cavity facet extends, and the second semiconductor laser element which has a second recess corresponding to the groove for cleavage, the second recess extending in a direction in which the second cavity facet extends. Accordingly, the first and second semiconductor laser elements are cleaved starting from the grooves for cleavage, which form the first and second recesses after the cleavage, in the direction substantially perpendicular to the direction in which the first and second optical waveguides extend. Thus, in the first and second semiconductor laser elements, the cavity facets including the cleaved surfaces can be aligned in the cavity direction in substantially the same plane. It is therefore possible to obtain an integrated multi-wavelength semiconductor laser device including cavity facets of the respective semiconductor laser elements prevented from being misaligned in the cavity direction.

### BRIEF DESCRIPTION OF THE DRAWINGS

FIG. 1 is a perspective view showing a structure of a three-wavelength semiconductor laser device according to a first embodiment.

FIG. 2 is a plan view showing the structure of the three-wavelength semiconductor laser device according to the first embodiment shown in FIG. 1.

FIG. 3 is a view illustrating a manufacturing process of the three-wavelength semiconductor laser device according to the first embodiment shown in FIG. 1.

FIG. 4 is a view illustrating the manufacturing process of the three-wavelength semiconductor laser device according to the first embodiment shown in FIG. 1.

FIG. 5 is a view illustrating the manufacturing process of the three-wavelength semiconductor laser device according to the first embodiment shown in FIG. 1.

FIG. 6 is a view illustrating the manufacturing process of the three-wavelength semiconductor laser device according to the first embodiment shown in FIG. 1.

FIG. 7 is a view illustrating the manufacturing process of the three-wavelength semiconductor laser device according to the first embodiment shown in FIG. 1.

FIG. 8 is a view illustrating the manufacturing process of the three-wavelength semiconductor laser device according to the first embodiment shown in FIG. 1.

FIG. 9 is a view illustrating the manufacturing process of the three-wavelength semiconductor laser device according to the first embodiment shown in FIG. 1.

FIG. 10 is a view illustrating the manufacturing process of the three-wavelength semiconductor laser device according to the first embodiment shown in FIG. 1.

FIG. 11 is a perspective view showing a structure of a two-wavelength semiconductor laser element according to a modification of the first embodiment.

FIG. 12 is a perspective view showing a structure of a three-wavelength semiconductor laser device according to a second embodiment.

FIG. 13 is a view illustrating a manufacturing process of the three-wavelength semiconductor laser device according to the second embodiment shown in FIG. 12.

FIG. 14 is a perspective view showing a structure of a three-wavelength semiconductor laser device according to a third embodiment.

FIG. 15 is a view illustrating a manufacturing process of the three-wavelength semiconductor laser device according to the third embodiment shown in FIG. 14.

FIG. 16 is a perspective view showing a structure of a three-wavelength semiconductor laser device according to a first modification of the third embodiment.

FIG. 17 is a perspective view showing a structure of a three-wavelength semiconductor laser device according to a second modification of the third embodiment.

FIG. 18 is a perspective view showing a structure of a three-wavelength semiconductor laser device according to a fourth embodiment.

FIG. 19 is a view illustrating a manufacturing process of the three-wavelength semiconductor laser device according to the fourth embodiment shown in FIG. 18.

FIG. 20 is a perspective view showing a structure of a three-wavelength semiconductor laser device according to a first modification of the fourth embodiment.

FIG. 21 is a perspective view showing a structure of a three-wavelength semiconductor laser device according to a second modification of the fourth embodiment.

FIG. 22 is a perspective view showing a structure of an RGB three-wavelength semiconductor laser device according to a fifth embodiment.

### DETAILED DESCRIPTION OF EMBODIMENTS

Descriptions are provided hereinbelow for embodiments based on the drawings. All of the drawings are provided to illustrate the respective examples only. No dimensional proportions in the drawings shall impose a restriction on the embodiments. For this reason, specific dimensions and the like should be interpreted with the following descriptions taken into consideration. In addition, the drawings include parts whose dimensional relationship and ratios are different from one drawing to another.

Prepositions, such as “on”, “over” and “above” may be defined with respect to a surface, for example a layer surface, regardless of that surface's orientation in space. The preposition “above” may be used in the specification and claims even if a layer is in contact with another layer. The preposition “on” may be used in the specification and claims when a layer is not in contact with another layer, for example, when there is an intervening layer between them.

### First Embodiment

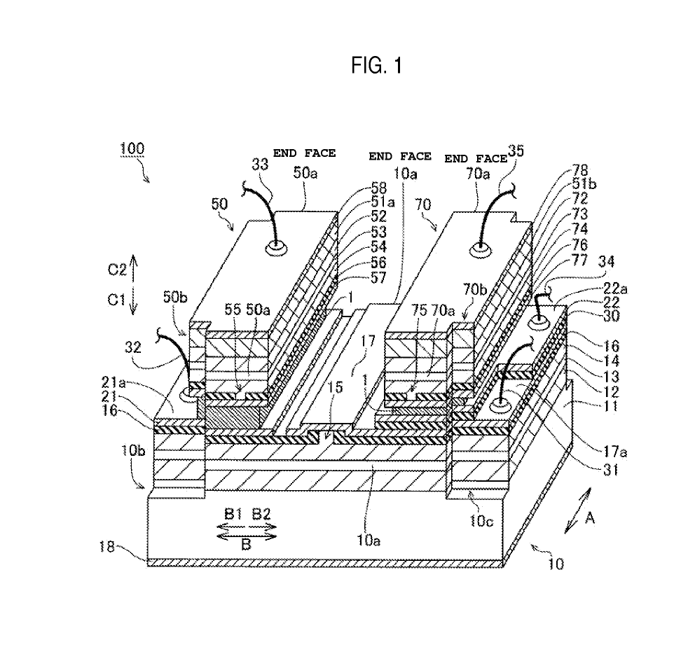

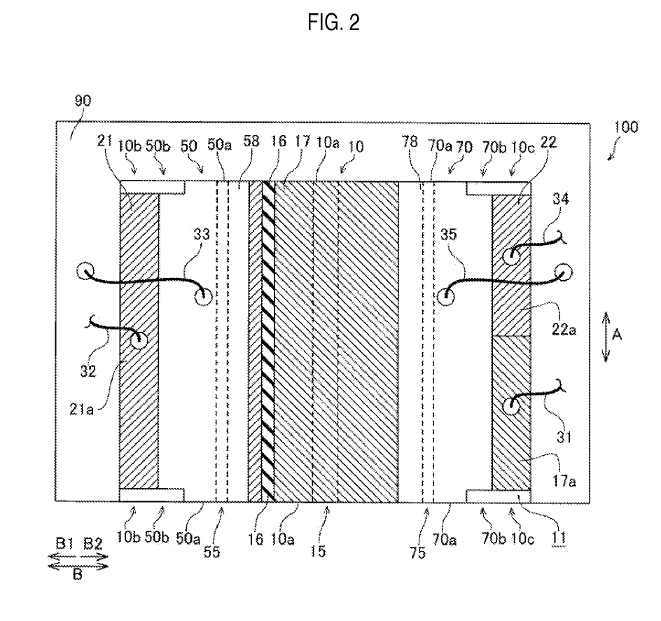

FIG. 1 is a perspective view showing a structure of a three-wavelength semiconductor laser device according to a first embodiment. FIG. 2 is a plan view showing the structure of the three-wavelength semiconductor laser device according to the first embodiment shown in FIG. 1. First, with reference to FIGS. 1 and 2, a description is given of a structure of a three-wavelength semiconductor laser device 100 according to the first embodiment.

As shown in FIG. 1, three-wavelength semiconductor laser device 100 according to the first embodiment is configured as a multi-wavelength laser device in which red semiconductor laser element 50 having an lasing wavelength of about 650 nm and infrared semiconductor laser element 70 having an lasing wavelength of about 780 nm are bonded to an upper surface of blue-violet semiconductor laser element 10 having an lasing wavelength of about 405 nm with conductive bonding layer 1 interposed therebetween. Here, conductive bonding layer 1 is made of a metallic layer of AuSn solder or the like. Note that, blue-violet semiconductor laser element 10 is an example of a “first semiconductor laser element” of the invention. Each of red semiconductor laser element 50 and infrared semiconductor laser element 70 is an example of a “second semiconductor laser element” of the invention. The upper surface of blue-violet semiconductor laser element 10 is an example of a “first surface” of the invention.

In the blue-violet semiconductor laser element 10, as shown in FIG. 1, a pair of cavity facets 10a substantially perpendicular to a main surface (the upper surface) of n-type GaN substrate 11 are formed at both ends thereof in the cavity direction (A direction). Additionally, in red semiconductor laser element 50, a pair of cavity facets 50a are formed in planes substantially the same as respective cavity facets 10a at both ends thereof in the cavity direction (A direction). In infrared semiconductor laser element 70, a pair of cavity facets 70a are formed in planes substantially the same as respective cavity facets 10a at both ends thereof in the cavity direction (A direction). Note that, cavity facets 10a are examples of a “first cavity facet” of the invention, and n-type GaN substrate 11 is an example of a “substrate” of the invention. Moreover, each of cavity facets 50a and 70a is an example of a “second cavity facet” of the invention.

Herein, in the first embodiment, as shown in FIG. 1, recesses 10b and 10c having end faces different from the cavity facet 10a are formed at both ends of each cavity facet 10a of blue-violet semiconductor laser element 10. Bottoms of the recesses 10b and 10c reach into the n-type GaN substrate 11. Moreover, at an end of each cavity facet 50a of red semiconductor laser element 50 in the B1 direction, recess 50b having an end surface different from cavity facet 50a is formed. Recess 50b is formed to extend in the C1 direction through all the semiconductor layers from the upper surface of red semiconductor laser element 50 to the lower surface thereof. Additionally, at an end of cavity facet 70a of infrared semiconductor laser element 70 in the B2 direction, recess 70b having an end surface different from cavity facet 70a is formed. Recess 70b is formed to extend in the C1 direction through all the semiconductor layers from the upper surface of infrared semiconductor laser element 70 to the lower surface thereof. Note that, each of recesses 10b and 10c is an example of a “first recess” of the invention, and each of recesses 50b and 70b is an example of a “second recess” of the invention. In addition, each of the upper surfaces of red semiconductor laser element 50 and infrared semiconductor laser element 70 is an example of a “second surface” of the invention, and each of the lower surfaces of red semiconductor laser elements 50 and infrared semiconductor laser element 70 is an example of a “third surface” of the invention.

In the first embodiment, as shown in FIG. 2, recesses 10b and 50b are arranged so as to substantially overlap with each other in a plan view of three-wavelength semiconductor laser device 100. Recesses 10c and 70b are also arranged so as to substantially overlap with each other. Accordingly, as shown in FIG. 1, recesses 10b and 50b are formed so as to extend starting from substantially the same position in the B1 direction toward an end of three-wavelength semiconductor laser device 100 (in B1 direction). At the same time, recesses 10c and 70b are formed so as to extend starting from substantially the same position in the B2 direction toward an end of three-wavelength semiconductor laser device 100 (in B2 direction). Thus, in three-wavelength semiconductor laser device 100, recesses extending substantially linearly in C1 direction continuously from upper surfaces of red and infrared semiconductor laser elements 50 and 70 into n-type GaN substrate 11 are formed at both ends of cavity facet 10a in the B direction.

In addition, in the first embodiment, recesses 10b and 10c are formed in respective regions (at the ends in the B direction) except for a region where the optical waveguide (in the vicinity of later described ridge 15) is formed. Moreover, recesses 50b and 70b are formed in respective regions (at the ends in the B direction) except for regions where the optical waveguides (in the vicinities of later-described ridges 55 and 75) are formed, respectively.

Note that, each of recesses 10b, 10c, 50b, and 70b is a part of grooves for cleavage (scribed groove 40 (groove portion 40a)) remaining in each chip of three-wavelength semiconductor laser device 100. Here, the grooves for cleavage are used for dividing a wafer including three-wavelength semiconductor laser device 100 in the B direction (bar cleavage) at a manufacturing process later described.

Moreover, in cavity facets 10a, 50a, and 70a of the semiconductor laser elements (10, 50, and 70), dielectric multilayer films (not shown) are formed by facet coating. Herein, each dielectric multilayer film can be a monolayer or multilayer film made of GaN, AlN, BN, Al₂O₃, SiO₂, ZrO₂, Ta₂O₅, Nb₂O₅, La₂O₃, SiN, AlO N, MgF₂, or a material having a mixed proportion different from those materials, such as Ti₃O₅ and Nb₂O₃.

Furthermore, as shown in FIG. 1, blue-violet semiconductor laser element 10 includes: n-type cladding layer 12 made of n-type AlGaN; active layer 13; and p-type cladding layer 14 made of p-type AlGaN, which are formed on n-type GaN substrate 11. Here, active layer 13 has a multiple quantum well (MQW) structure in which quantum well layers made of InGaN with a high content of In and barrier layers made of InGaN with a low content of In are alternately stacked on each other. Thus, blue-violet semiconductor laser element 10 is formed of nitride compound semiconductor layers.

Between n-type cladding layer 12 and active layer 13, other semiconductor layers may be formed such as an optical guiding layer (not shown) and a carrier block layer (not shown). Moreover, on a side of n-type cladding layer 12 opposite side of active layer 13, another semiconductor layer such as a contact layer (not shown) may be formed. Between active layer 13 and p-type cladding layer 14, other semiconductor layers may be formed such as an optical guiding layer (not shown) and a carrier block layer (not shown). Moreover, on a side of p-type cladding layer 14 opposite side of active layer 13, another semiconductor layer such as a contact layer (not shown) may be formed. Furthermore, active layer 13 may have a monolayer or single quantum well (SQW) structure or the like.

As shown in FIG. 1, p-type cladding layer 14 includes a protruding section formed substantially at the center of the element in the B direction and flat sections extending on both sides of the protruding section (in B1 and B2 directions). The protruding section of p-type cladding layer 14 constitutes ridge 15, which forms an optical waveguide in active layer 13. In addition, ridge 15 has a width of about 1.5 μm in the B direction and extends along the cavity direction (A direction).

Current block layer 16 made of SiO₂ is formed so as to cover upper surfaces of the flat sections of p-type cladding layer 14 and side surfaces of ridge 15. As shown in FIG. 1, p-side pad electrode 17 made of Au or the like is formed so as to extend in the A direction and cover upper surfaces of p-type cladding layer 14 and current block layers 16. Note that, between ridge 15 and p-side pad electrode 17, a contact layer (not shown), an ohmic electrode layer (not shown), or the like may be formed, each of which preferably has a band gap smaller than that of p-type cladding layer 14.

As shown in FIG. 2, electrode layer 21 is formed so as to cover a region, which does not overlap p-side pad electrode 17, of the upper surfaces of current block layers 16 on a side of ridge 15 in B1 direction. At an end of electrode layer 21 in B1 direction, wire bonding region 21a is provided.

As shown in FIG. 2, p-side pad electrode 17 is formed so as to extend in the B2 direction from ridge 15 to an end of blue violet semiconductor laser element 10. In addition, insulating film 30 extending in the A direction (see FIG. 1) is formed so as to cover a region that is bonded to infrared semiconductor laser element 70 and wire bonding region 22a region of the upper surface of p-side pad electrode 17 extending in the B2 direction. At the same time, electrode layer 22 is formed to cover an upper surface of insulating film 30. Moreover, insulating film 30 and electrode layer 22 are patterned so that wire bonding region 17a of p-side pad electrode 17 is exposed in a part of region at an end of blue-violet semiconductor laser element 10 in the B2 direction as shown in FIG. 1. Furthermore, electrode layer 22 includes wire bonding region 22a at an end thereof in the B2 direction.

On a lower surface of n-type GaN substrate 11, there is formed n-side electrode 18 including Ti, Pt, and Au layers sequentially stacked from the side of n-type GaN substrate 11.

Red semiconductor laser element 50 includes: n-type cladding layer 52 made of n-type AlGaInP; active layer 53; and p-type cladding layer 54 made of p-type AlGaInP, which are formed on a lower surface of n-type contact layer 51a made of n-type GaAs. Here, active layer 53 includes quantum well layers made of GaInP and barrier layers made of AlGaInP alternately stacked on each other. Thus, red semiconductor laser element 50 is formed of semiconductor layers of compounds containing P (phosphorus).

Note that, between n-type cladding layer 52 and active layer 53, other semiconductor layers may be formed such as an optical guiding layer (not shown) and a carrier block layer (not shown). Moreover, on a side of n-type cladding layer 52 opposite side of active layer 53, another semiconductor layer may be formed. Between active layer 53 and p-type cladding layer 54, other semiconductor layers may be formed such as an optical guiding layer (not shown) and a carrier block layer (not shown). Furthermore, on a side of p-type cladding layer 54 opposite side of active layer 53, another semiconductor layer such as a contact layer (not shown) may be formed. Active layer 53 may have a monolayer or SQW structure or the like.

As shown in FIG. 1, p-type cladding layer 54 includes a protruding section and flat sections. The protruding section is formed at a position slightly away from substantially the center of the element on one side (in the B2 direction) so as to protrude downward (in the C1 direction). The flat sections extend on both sides of the protruding section. The protruding section of p-type cladding layer 54 constitutes ridge 55, which forms an optical waveguide in active layer 53. Ridge 55 has a width of about 2 μm in the B direction and extends along the cavity direction (A direction).

Current block layer 56 made of SiO₂ is formed so as to cover the lower surfaces of the flat sections of p-type cladding layer 54 and side surfaces of ridge 55. P-side pad electrode 57 made of Au or the like is formed so as to cover lower surfaces of p-type cladding layer 54 and current block layer 56. Note that, between ridge 55 and p-side pad electrode 57, a contact layer (not shown), an ohmic electrode layer (not shown), or the like may be formed, each of which preferably has a band gap smaller than that of p-type cladding layer 54. On an upper surface of n-type contact layer 51a, n-side electrode 58 including Ti, Pt, and Au layers are sequentially stacked from the n-type contact layer 51a side.

Infrared semiconductor laser element 70 includes: n-type cladding layer 72 made of n-type AlGaAs; active layer 73; and p-type cladding layer 74 made of p-type AlGaAs, which are formed on a lower surface of n-type contact layer 51b made of n-type GaAs. Here, active layer 73 includes quantum well layers made of AlGaAs with a low content of Al and barrier layers made of AlGaAs with a high content of Al, which are alternately stacked on each other. Thus, infrared semiconductor laser element 70 is formed of semiconductor layers of compounds containing As.

Note that, between n-type cladding layer 72 and active layer 73, other semiconductor layers may be formed such as an optical guiding layer (not shown) and a carrier block layer (not shown). Moreover, on a side of n-type cladding layer 72 opposite side of active layer 73, another semiconductor layer may be formed. Between active layer 73 and p-type cladding layer 74, other semiconductor layers may be formed such as an optical guiding layer (not shown) and a carrier block layer (not shown). Furthermore, on a side of p-type cladding layer 74 opposite side of active layer 73, another semiconductor layer such as a contact layer (not shown) may be formed. Active layer 73 may have a monolayer or SQW structure or the like.

As shown in FIG. 1, p-type cladding layer 74 includes a protruding section and flat sections. The protruding section is formed at a position slightly away from substantially the center of the element on one side (in the B1 direction) so as to protrude downward (in the C1 direction). The flat sections extend on both sides of the protruding section. The protruding section of p-type cladding layer 74 constitutes ridge 75, which forms an optical waveguide in active layer 73. Ridge 75 has a width of about 3 μm in the B direction and extends along the cavity direction (A direction).

Current block layer 76 made of SiO₂ is formed so as to cover lower surfaces of the flat sections of p-type cladding layer 74 and side surfaces of ridge 75. P-side pad electrode 77 made of Au or the like is formed so as to cover lower surfaces of p-type cladding layer 74 and current block layer 76. Note that, between ridge 75 and p-side pad electrode 77, a contact layer (not shown), an ohmic electrode layer (not shown), or the like may be formed, each of which preferably has a band gap smaller than that of p-type cladding layer 74. On the upper surface of n-type contact layer 51b, there is formed n-side electrode 78 including Ti, Pt, and Au layers sequentially stacked from the n-type contact layer 51b side.

As shown in FIG. 1, p-side pad electrode 57 of red semiconductor laser element 50 is bonded to electrode layer 21 on blue-violet semiconductor laser element 10 with conductive bonding layer 1 interposed therebetween. P-side pad electrode 77 of infrared semiconductor laser element 70 is bonded to electrode layer 22 on blue-violet semiconductor laser element 10 with conductive bonding layer 1 interposed therebetween.

As shown in FIGS. 1 and 2, blue-violet semiconductor laser element 10 is connected to a lead terminal (not shown) through metallic wire 31, which is wire-bonded to wire bonding region 17a of p-side pad electrode 17, while n-side electrode 18 thereof is electrically connected to base 90 (see FIG. 2) through a conductive bonding layer (not shown). Moreover, red semiconductor laser element 50 is connected to a lead terminal (not shown) through metallic wire 32, which is wire-bonded to wire bonding region 21a of electrode layer 21, and is connected to base 90 (see FIG. 2) through metallic wire 33, which is wire-bonded to n-side electrode 58. Furthermore, infrared semiconductor laser element 70 is connected to a lead terminal (not shown) through metallic wire 34, which is wire-bonded to wire bonding region 22a of electrode layer 22, and is connected to base 90 (see FIG. 2) through metallic wire 35, which is wire-bonded to n-side electrode 78. Thus, three-wavelength semiconductor laser device 100 has a configuration in which the p-side electrodes of the semiconductor laser elements are respectively connected to the lead terminals insulated from each other while n-side electrodes are connected to the common terminal (a common cathode configuration).

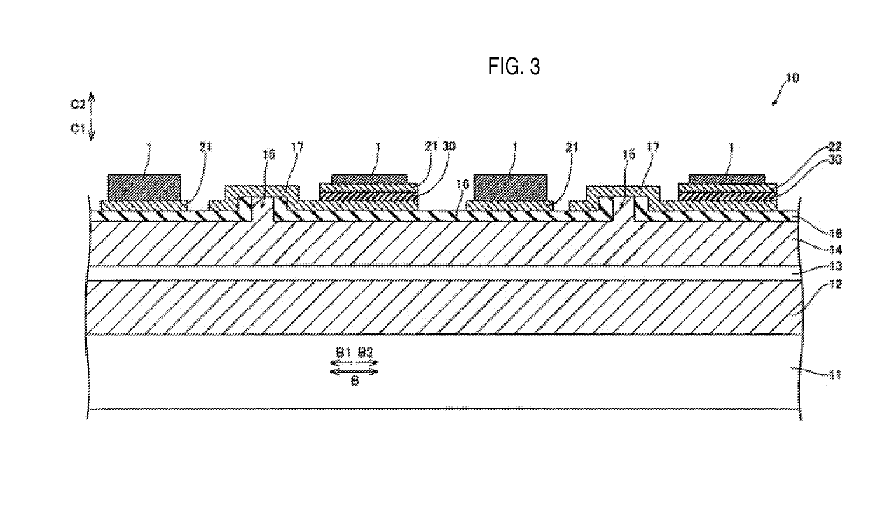

FIGS. 3 to 10 are views illustrating a manufacturing process of the three-wavelength semiconductor laser device according to the first embodiment shown in FIG. 1. Next, with reference to FIGS. 1 to 10, a description is given of the manufacturing process of three-wavelength semiconductor laser device 100 according to the first embodiment.

In the manufacturing process of three-wavelength semiconductor laser device 100 according to the first embodiment, as shown in FIG. 3, on the upper surface of n-type GaN substrate 11, n-type cladding layer 12, active layer 13, and p-type cladding layer 14 are first formed sequentially by a metal-organic chemical vapor deposition (MOCVD) method.

Next, as shown in FIG. 3, regions except an optical waveguide of p-type cladding layer 14 are etched using photolithography and dry etching to form ridges 15 extending in the A direction (see FIG. 1). After that, current block layers 16 are formed on the upper surface of p-type cladding layer 14 except for ridges 15. P-side pad electrodes 17 are formed so as to cover the upper surfaces of ridges 15 and predetermined regions of the upper surfaces of current block layers 16 in the vicinity of ridges 15.

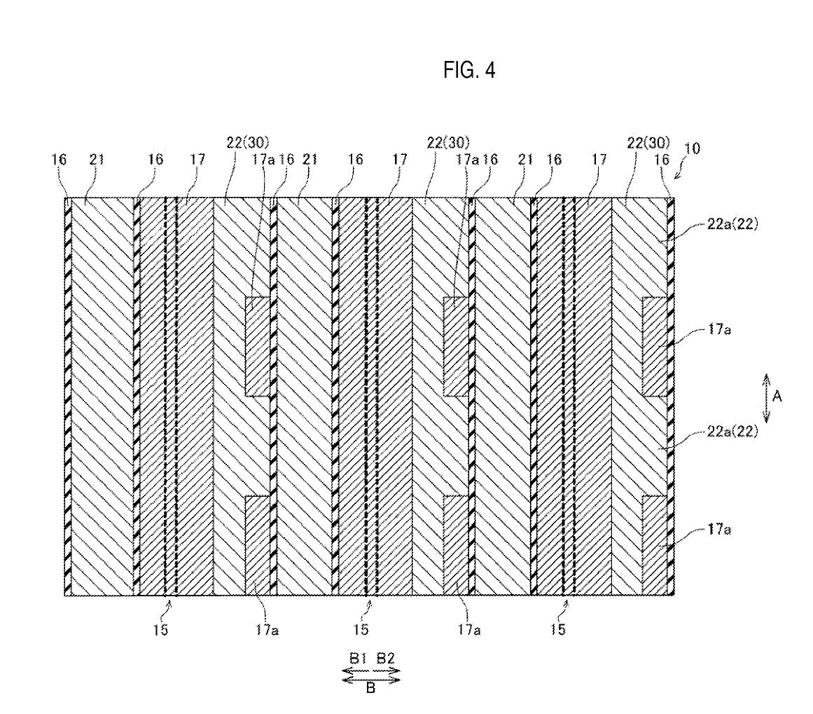

Subsequently, as show in FIG. 3, electrode layers 21 are formed on the upper surfaces of current block layers 16 on the side of respective ridges 15 in the B1 direction, and insulating films 30 are formed so as to cover predetermined regions of the upper surfaces of p-side pad electrodes 17 on the side of respective ridges 15 in the B2 direction. At this time, as shown in FIG. 4, insulating films 30 (see FIG. 3) are patterned and formed on p-side pad electrodes 17 so that only wire bonding regions 17a of p-side pad electrodes 17 are exposed to the outside.

Thereafter, electrode layers 22 are formed using vacuum deposition so as to cover upper surfaces of insulating films 30 (see planar shapes of electrode layers 22 in FIG. 4), and conductive bonding layers 1 are previously formed on electrode layers 21 and 22. At this time, as shown in FIG. 3, the thicknesses of conductive bonding layers 1 are adjusted so that the upper surfaces of conductive bonding layers 1 on both sides of each ridge 15 are substantially at the same position in the C2 direction. A wafer including blue-violet semiconductor laser element 10 except for n-side electrode 18 is thus formed.

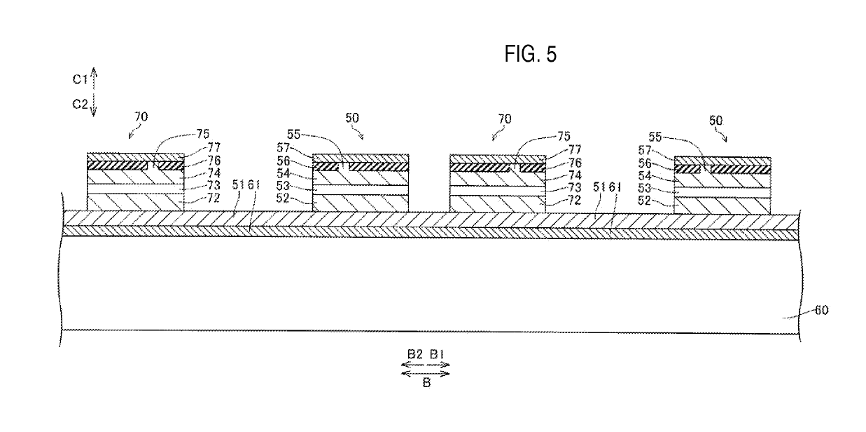

As shown in FIG. 5, etching stop layer 61 made of n-type AlGaAs and n-type contact layer 51 are sequentially formed on the upper surface of n-type GaAs substrate 60 using an MOCVD method. Subsequently, n-type cladding layer 72, active layer 73, and p-type cladding layer 74, which constitute infrared semiconductor laser element 70, are sequentially formed on the upper surface of n-type contact layer 51. N-type cladding layer 72, active layer 73, and p-type cladding layer 74 are then partially etched to expose portions of the upper surface of n-type contact layer 51. On a part of each exposed portion, n-type cladding layer 52, active layer 53, and p-type cladding layer 54, which constitute red semiconductor laser element 50, are sequentially formed.

Infrared semiconductor laser element 70 is formed before forming red semiconductor laser element 50 in the embodiment. However it is not limited to this. Infrared semiconductor laser element 70 may be formed after forming red semiconductor laser element 50. That is, subsequently, n-type cladding layer 52, active layer 53, and p-type cladding layer 54, which constitute red semiconductor laser element 50, are sequentially formed on the upper surface of n-type contact layer 51. N-type cladding layer 52, active layer 53, and p-type cladding layer 54 are then partially etched to expose portions of the upper surface of n-type contact layer 51. On a part of each exposed portion, n-type cladding layer 72, active layer 73, and p-type cladding layer 74, which constitute infrared semiconductor laser element 70, are sequentially formed. Thereafter, ridges 55 and 75 extending along the A direction (see FIG. 1) are formed in p-type cladding layers 54 and 74. Current block layers 56 and 76 are formed on upper surfaces of p-type cladding layers 54 and 74 except for ridges 55 and 75, respectively. On upper surfaces of ridges 55 and 75 as well as current block layers 56 and 76, p-side pad electrodes 57 and 77 are formed, respectively.

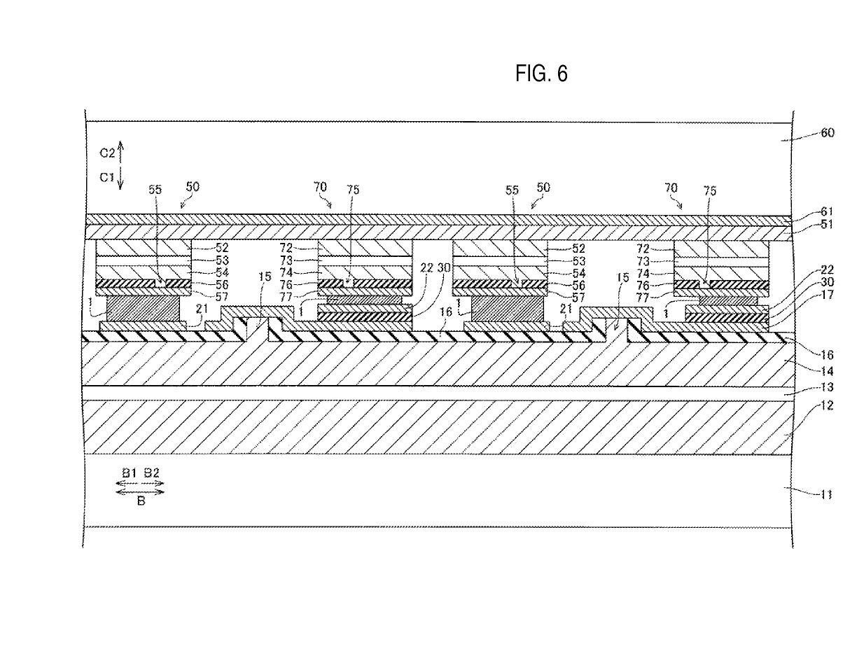

As shown in FIG. 6, then, electrode layers 21 and 22 provided for the wafer including blue-violet semiconductor laser element 10 and the wafer including red and infrared semiconductor laser elements 50 and 70 formed on n-type GaAs substrate 11 are placed opposite to each other, and conductive bonding layer 1 is melted under the condition of a temperature of about 295° C. and a load of about 100 N/cm², thus bonding the wafers.

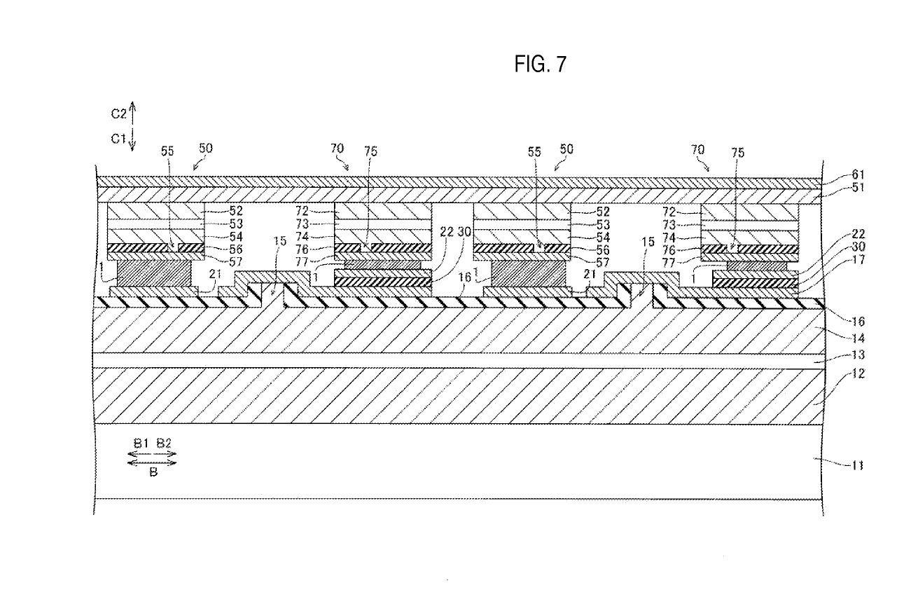

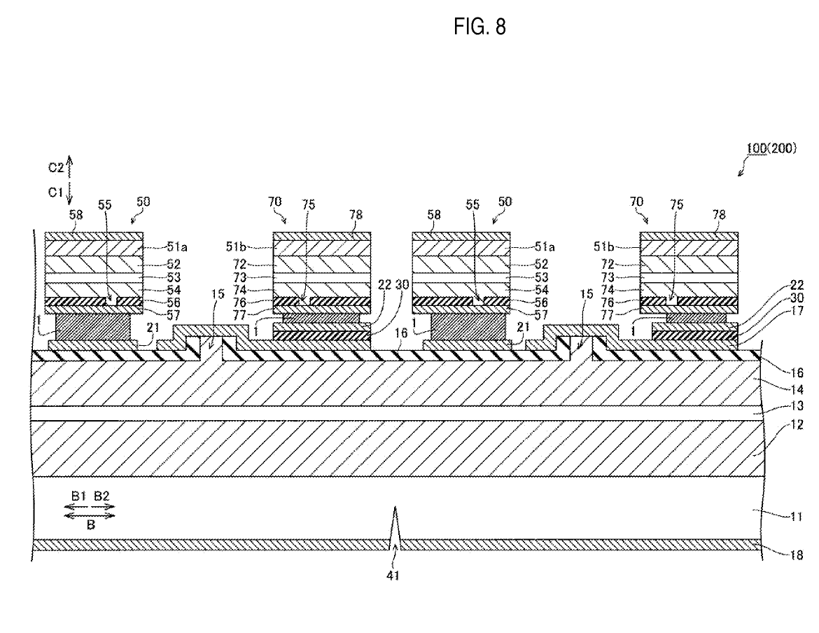

Subsequently, as shown in FIG. 7, n-type GaAs substrate 60 (see FIG. 6) is completely removed by etching up to etching stop layer 61. After that, as shown in FIG. 8, etching stop layer 61 (see FIG. 7) is then removed by wet etching using hydrofluoric acid or hydrochloric acid to expose n-type contact layer 51. Furthermore, portions of n-type contact layer 51 above p-side pad electrode 17 of blue-violet semiconductor laser element 10 are removed by wet etching using sulfuric acid.

Thereafter, n-side electrodes 58 and 78 are formed on upper surfaces of n-type contact layers 51a and 51b using vacuum deposition. As shown in FIG. 8, then, the lower surface of n-type GaN substrate 11 is ground so that n-type GaN substrate 11 has about 100 μm thickness, and n-side electrode 18 is formed on the lower surface of n-type GaN substrate 11 using vacuum deposition. In such a manner, a wafer including three-wavelength semiconductor laser device 100 (see FIG. 8) is formed. The wafer including three-wavelength semiconductor laser device 100 is then cleaved into bars.

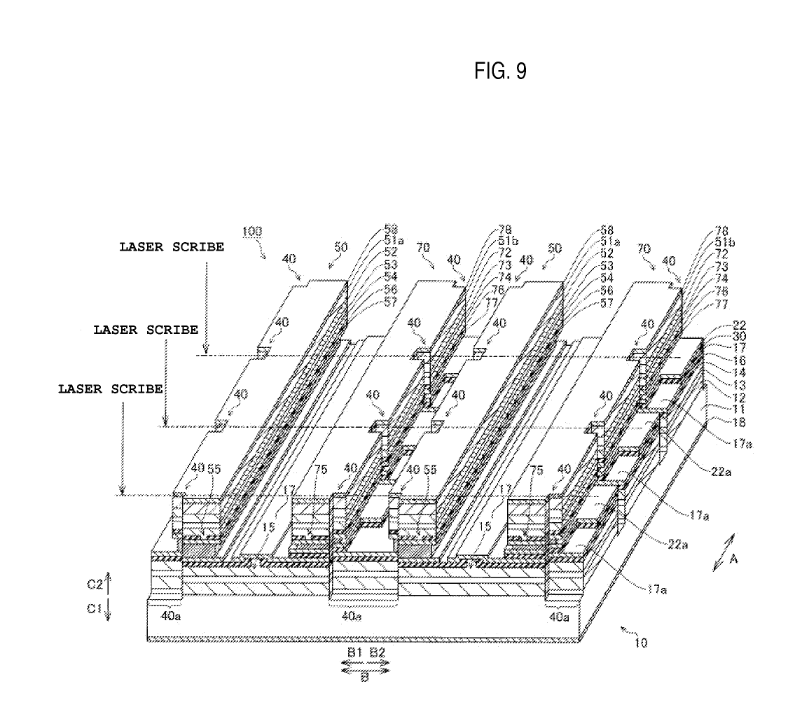

Herein, in the manufacturing process of the first embodiment, as shown in FIG. 9, dashed line-like scribed grooves 40 extending substantially linearly in the B direction are formed from the side of red and infrared semiconductor laser elements 50 and 70 (from the upper side of the wafer) using laser scribing. Dashed line-like scribed grooves 40 are arranged in the A direction at intervals substantially equal to the length of the cavities. At this time, groove portions 40a are continuous in the B2 direction within a section from an end part of infrared semiconductor laser element 70 in the B2 direction through the upper surface of the blue-violet semiconductor laser element 10 (electrode layer 22) to an end part of red semiconductor laser element 50 in the B1 direction. Each of groove portions 40a has such a depth such that the bottom thereof reaches into n-type GaN substrate 11.

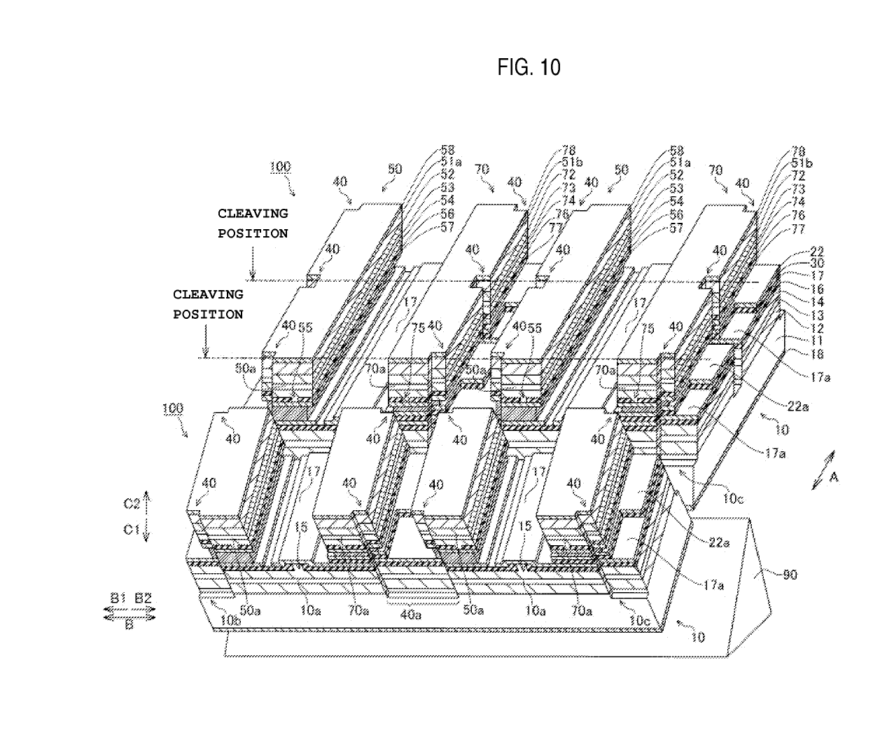

As shown in FIG. 10, in this state, knife jig 90 extending in the B direction is located on the lower surface of the n-type GaN substrate 11 of the wafer corresponding to each place where scribed grooves 40 (see FIG. 9) are formed (n-side electrode 18 side) while a load is applied to the lower side of n-type GaN substrate 11 serving as a fulcrum so as to open the upper side of the wafer, thus cleaving the wafer at scribed grooves 40 in the B direction. The wafer is cleaved into bars each including three-wavelength semiconductor laser device 100 arranged in the B direction in parallel to each other as shown in FIG. 10. At this time, since the wafer is cleaved with the fulcrum set at the lower surface of n-type GaN substrate 11 so as to open the upper part of the wafer, loading to around the ridges of the semiconductor laser elements is prevented. The wafer is thus divided in the A direction with the horizontal positions of the cavity facets 10a, 50a, and 70a being aligned.

Subsequently, the bars each including three-wavelength semiconductor laser device 100 are subjected to facet coating. On each of cavity facets 10a, 50a, and 70a, a dielectric multilayer film (not shown) made of an AlN film, an Al₂O₃ film, or the like is formed.

Subsequently, as shown in FIG. 8, grooves for division 41 extending in the A direction (see FIG. 10) are formed using laser scribing on the rear side of n-type GaN substrate 11 of the wafer bars (on the n-side electrode 18 side). The wafer bars are divided into chips along the A direction at the positions of the grooves for division 41. The wafer bars are divided into individual laser chips, thus fabricating a large number of three-wavelength semiconductor laser devices 100 (see FIG. 1).

In the first embodiment, as described above, the three-wavelength semiconductor laser device 100 includes: blue-violet semiconductor laser element 10 having recesses 10b and 10c extending in the direction in which cavity facet 10a extends (B direction); red semiconductor laser element 50 having recess 50b extending in the direction in which cavity facet 50a, formed in substantially the same plane as the cavity facet 10a, extends; and infrared semiconductor laser element 70 having recess 70b extending in the direction in which cavity facet 70a, formed in substantially the same plane as cavity facet 10a, extends. The recesses 10b and 50b are formed in substantially the same plane as cavity facet 10a, and recesses 10c and 70b are formed in substantially the same plane as cavity facet 10a. Accordingly, with the above manufacturing process, cavity facet 10a including a cleaved surface cleaved starting from recesses 10b and 10c of blue-violet semiconductor laser element 10 as well as cavity facets 50b and 70b of red and infrared semiconductor laser elements 50 and 70 which respectively include cleaved surfaces cleaved starting from recesses 50b and 70b can be formed so as to be aligned substantially in the same plane in the cavity direction (A direction). As a result, in three-wavelength semiconductor laser device 100, cavity facets 10a, 50a, and 70a of blue-violet, red, and infrared laser semiconductor elements can be prevented from being misaligned in the cavity direction (A direction).

In the first embodiment, recess 50b extends from the upper surface of red semiconductor laser element 50 in the C2 direction to reach the lower surface thereof which is bonded to blue-violet semiconductor laser element 10, and recess 70b is formed from the upper surface of infrared semiconductor laser element 70 in the C2 direction to reach the lower surface thereof which is bonded to blue-violet semiconductor laser element 10. Recesses 50b and 70b therefore penetrate red and infrared semiconductor laser elements 50 and 70 in the thickness direction thereof (in the C1 direction), respectively. This facilitates cleaving the wafer including three-wavelength semiconductor laser device 100 into bars. Cavity facets 50aand 70a can therefore be easily formed.

In the first embodiment, recesses 10b and 10c extend from the upper surface of blue-violet semiconductor laser element 10 in the C2 direction toward n-type GaN substrate 11 so as to be continuous with recesses 50b and 70b, respectively. In blue-violet semiconductor laser element 10, therefore, recesses 10b and 10c continuous to recesses 50b and 70b penetrating red and infrared semiconductor laser elements 50 and 70 in the thickness direction (C1 direction) can be formed. Accordingly, with the manufacturing process, recess 50b for forming cavity facet 50a and recess 10b for forming cavity facet 10a (groove for cleavage 40) can be simultaneously formed in the thickness direction of three-wavelength semiconductor laser device 100, as well as recess 70b for forming cavity facet 70a and recess 10c for forming cavity facet 10a (groove for cleavage 40) can be simultaneously formed in the thickness direction of three-wavelength semiconductor laser device 100.

In the first embodiment, formation regions of respective recesses 10b and 50b are arranged so as to overlap with each other in a plan view, while formation regions of recesses 10c and 70b are arranged so as to overlap with each other in a plan view. Accordingly, the planar regions of recesses 10b and 50b overlap with each other in the direction in which cavity facet 10a extend (along the B direction), while recesses 10b and 70b overlap with each other in the direction in which cavity facet 10a extend (in B direction). With the manufacturing process, the wafer including three-wavelength semiconductor laser device 100 is cleaved (bar cleavage) starting from recesses 50b (70b) and recesses 10b (10c) which are formed at substantially the same position as respective recesses 70b (50b) in the B direction. Cavity facets 10a, 50a, and 70a of three-wavelength semiconductor laser device 100 can therefore be simultaneously formed.

In the first embodiment, recesses 10b and 10c are formed in the vicinity of the ends of cavity facet 10a in the direction in which the cavity facet 10a extends. Moreover, recess 50b is formed in the vicinity of the end of cavity facet 50a on the same side where the recess 10b is formed, while recess 70b is formed in the vicinity of the end of cavity facet 70a on the same side where the recess 10b is formed. Accordingly, blue-violet, red, and infrared semiconductor laser elements 10, 50, and 70, include recesses (recesses 10b and 50b as well as recesses 10c and 70b) in the vicinities of the ends of cavity facets 10a, 50a, and 70a, respectively, so that blue-violet and red semiconductor laser elements include respective recesses 10b and 50b on the same side (in B1 direction) while blue-violet and infrared semiconductor laser elements include respective recesses 10c and 70b on the same side (in B2 direction). Unlike the case where there are no recesses formed in the vicinities of the ends of the cavity facets 10a, 50a, and 70a, therefore, it is possible to prevent the semiconductor element layers (12, 13, 14, 51a, 51b, 52, 53, 54, 72, 73, and 74) from being broken or cracked in the vicinities of the ends of cavity facets 10a, 50a, and 70a.

In the first embodiment, active layer 13 is made of nitride compound semiconductors, and active layers 53 and 73 are made of AlGaInP compound semiconductors and AlGaAs compound semiconductors, respectively. Accordingly, three-wavelength semiconductor laser device 100 can include blue-violet semiconductor laser element 10 and red and infrared semiconductor laser elements 50 and 70 emitting respective red and infrared laser light beams, which are different from those of blue-violet semiconductor laser element 10.

In the first embodiment, moreover, with the above manufacturing process, red and infrared semiconductor laser elements 50 and 70 can be simultaneously bonded to blue-violet semiconductor laser element 10, after being formed on the same growth substrate (n-type GaAs substrate 60). The manufacturing process can therefore be facilitated.

### Modification of First Embodiment

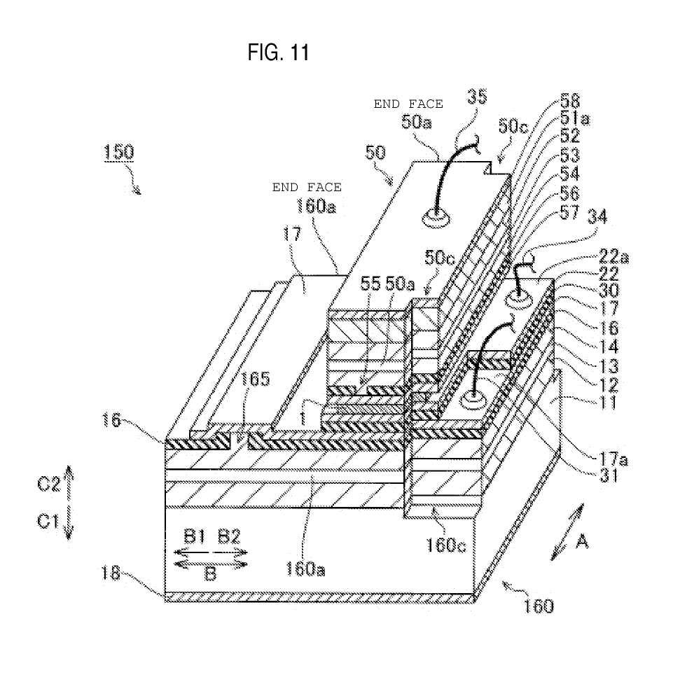

FIG. 11 is a perspective view showing a structure of a two-wavelength semiconductor laser device according to a modification of the first embodiment. With reference to FIG. 11, in the modification of the first embodiment, a description is given of a case where two-wavelength semiconductor laser device 150 including two wavelength laser elements is formed by bonding red semiconductor laser element 50 to the upper surface of blue-violet semiconductor laser element 160. Note that, blue violet semiconductor laser element 160 is an example of a “first semiconductor laser element” of the invention, and the upper surface of blue-violet semiconductor laser element 160 is an example of the “first surface” of the invention.

In the modification of the first embodiment, as shown in FIG. 11, in blue-violet semiconductor laser element 160, ridge 165 is formed at a position a predetermined distance (approximately 50 μm, for example) away in the B1 direction from substantially the center of the element in the B direction.

P-side pad electrode 17 of blue-violet semiconductor laser element 160 is formed so as to extend from the position of ridge 165 to the end of blue-violet semiconductor laser element 160 in the B2 direction. The structures of insulating film 30 and electrode layer 22 on p-side pad electrode 17 are the same as those of the first embodiment.

In the modification of the first embodiment, as shown in FIG. 11, at an end of cavity facet 160a of blue-violet semiconductor laser element 160 in the B2 direction, recess 160c is formed, which has an end face different from the cavity facet 160a. The bottom of the recess 160c reaches into n-type GaN substrate 11. At an end of cavity facet 50a of red semiconductor laser element 50 in the B2 direction, recess 50c is formed, which has an end face different from the cavity facet 50a. The recess 50c is formed so as to extend in the C1 direction across all the semiconductor layers between the upper and lower surfaces of red semiconductor laser element 50. In two-wavelength semiconductor laser device 150, therefore, at the end of each cavity facet 160a in the B2 direction, a single continuous recess is formed which substantially linearly extends in the C1 direction from the upper surface of red semiconductor laser element 50 into n-type GaN substrate 11. Cavity facet 160a is an example of the “first cavity facet” of the invention. Recesses 160c and 50c are examples of the “first and second recesses” of the invention, respectively.

The other parts of the structure and manufacturing process of two-wavelength semiconductor laser device 150 according to the modification of the first embodiment are the same as those of the aforementioned first embodiment.

In the modification of the first embodiment, as described above, two-wavelength semiconductor laser device 150 includes: blue-violet semiconductor laser element 160 having recess 160c extending in the direction in which cavity facet 160a extends (in B direction); and red semiconductor laser element 50 having recess 50c extending in the direction in which cavity facet 50a, formed in substantially the same plane as cavity facet 160a, extends (in B direction). Accordingly, recesses 160c and 50c are formed in substantially the same plane as cavity facet 160a. With the manufacturing process, cavity facet 160a including a cleaved surface cleaved starting from recess 160c of blue-violet semiconductor laser element and cavity facet 50a including a cleaved surface cleaved starting from recess 50c of red semiconductor laser element can therefore be formed so as to be aligned in substantially the same plane in the cavity direction (in A direction). As a result, two-wavelength semiconductor laser device 150 can prevent cavity facets 160a and 50a of respective blue-violet and red semiconductor laser elements 160 and 50 from being misaligned in the cavity direction. Note that, the other effects of the modification of the first embodiment are the same as those of the above first embodiment.

### Second Embodiment

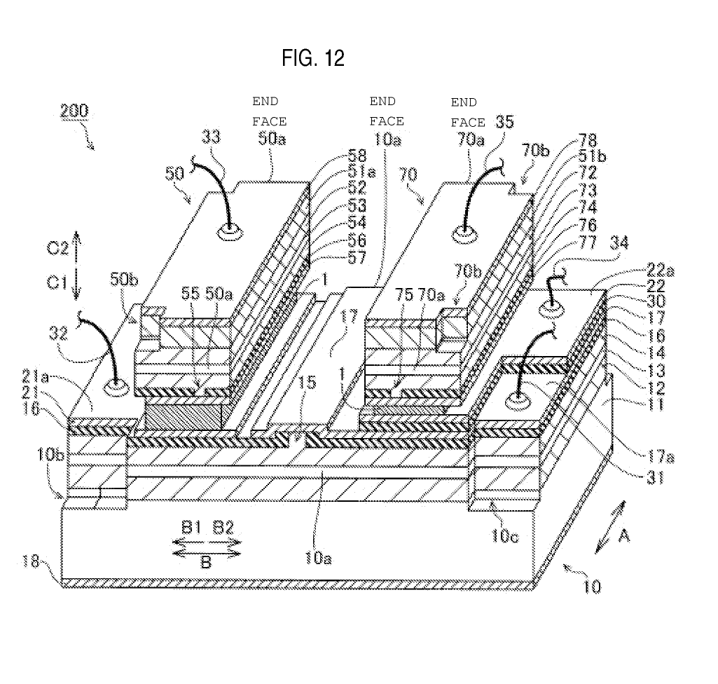

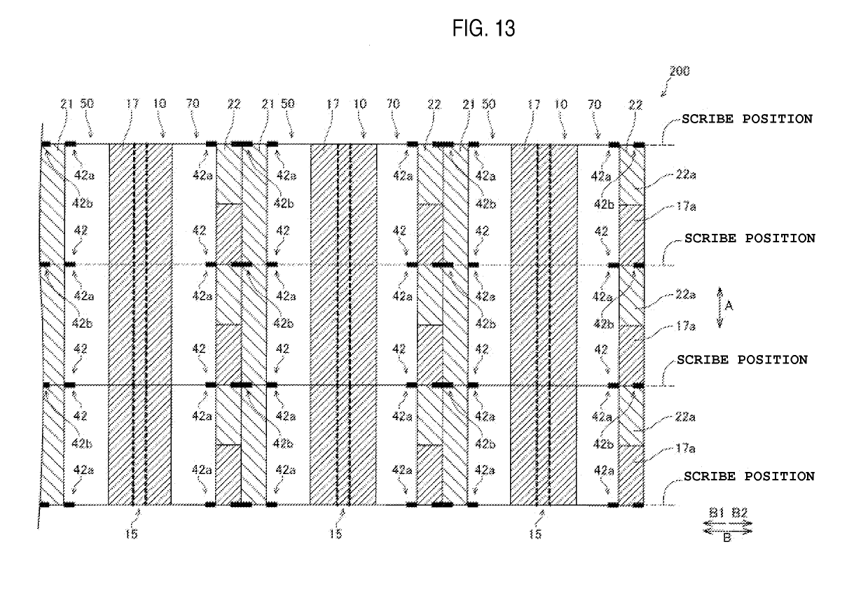

FIG. 12 is a perspective view showing a structure of a three-wavelength semiconductor laser device according to a second embodiment. FIG. 13 is a view illustrating a manufacturing process of the three-wavelength semiconductor laser device according to the second embodiment shown in FIG. 12. In this second embodiment, with reference to FIGS. 12 and 13, unlike the manufacturing process of the first embodiment, a description is given of a case where scribed grooves formed for bar cleavage of a wafer are separately formed for each semiconductor laser element constituting three-wavelength semiconductor laser device 200.

In three-wavelength semiconductor laser device 200 according to the second embodiment of the invention, as shown in FIG. 12, red and infrared semiconductor laser elements 50 and 70 are bonded to blue-violet semiconductor laser element 10 with conductive bonding layer 1 interposed therebetween.

In the second embodiment, recesses 10b and 50b of respective blue-violet and red semiconductor laser elements 10 and 50 are formed at positions different in the B1 direction. Recesses 10c and 70b of respective blue-violet and infrared semiconductor laser elements 10 and 70 are formed at positions different in the B2 direction.

Recesses 50b and 70b are formed to extend in the C1 direction from the upper surfaces of red and infrared semiconductor laser elements 50 and 70 so that the bottoms thereof are located within the semiconductor element layers, respectively. Note that, the other part of the structure of three-wavelength semiconductor laser device 200 according to the second embodiment is the same as that of the aforementioned first embodiment.

Next, with reference to FIGS. 8, 12, and 13, a description is given of a manufacturing process of three-wavelength semiconductor laser device 200 according to the second embodiment.

In the manufacturing process according to the second embodiment, a wafer including three-wavelength semiconductor laser device 200 (see FIG. 8) is first formed using the manufacturing process the same as that of the first embodiment, and is then cleaved into bars.

Herein, in the manufacturing process of the second embodiment, as shown in FIG. 13, dashed line-like scribed grooves 42 extending substantially linearly in the B direction are formed from the sides of red and infrared semiconductor laser elements 50 and 70 (the upper side of the wafer) using laser scribing. The dashed line-like scribed grooves 42 are arranged in the A direction at intervals substantially equal to the length of the cavity. At this time, laser scribing is performed so that groove portions 42a are formed only in an end part of red semiconductor laser element 50 in the B1 direction and an end part of infrared semiconductor laser element 70 in the B2 direction. Moreover, laser scribing is performed so that groove portions 42b are formed in the upper surface of blue-violet semiconductor laser element 10 (portions of electrode layer 22) within areas between the red and infrared semiconductor laser elements 50 and 70 adjacent to each other in the B direction. Dashed line-like scribed grooves 42 are thus formed so that groove portions 42a and 42b extend substantially linearly in the B direction in a plan view.

Note that, the other parts of the structure and manufacturing process of three-wavelength semiconductor laser device 200 according to the second embodiment are the same as those of the aforementioned first embodiment. The other effects of the second embodiment are the same as those of the above first embodiment.

### Third Embodiment

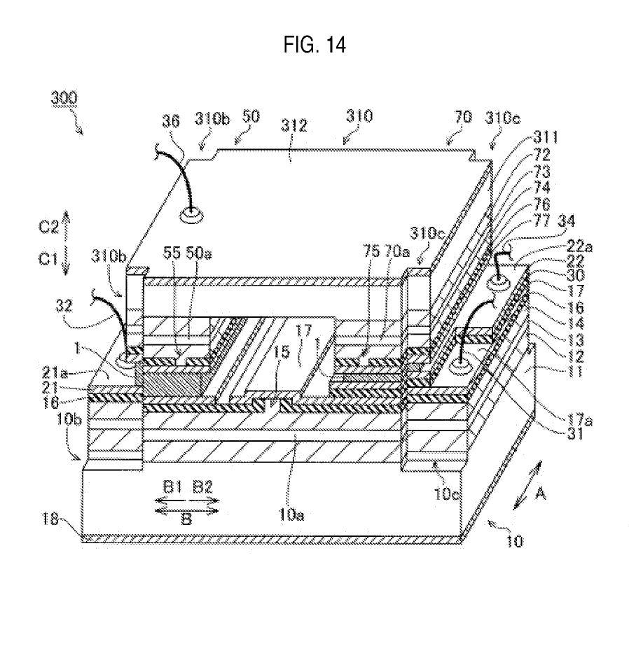

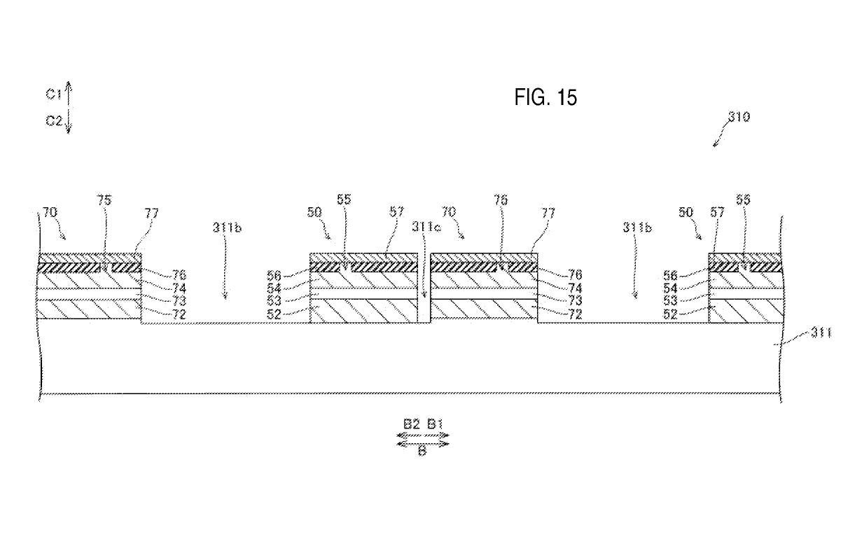

FIG. 14 is a perspective view showing a structure of a three-wavelength semiconductor laser device according to a third embodiment. FIG. 15 is a view illustrating a manufacturing process of the three-wavelength semiconductor laser device according to the third embodiment shown in FIG. 14. In this third embodiment, with reference to FIGS. 14, a description is first given of a case where three-wavelength semiconductor laser device 300 is formed by bonding blue-violet semiconductor laser element 10 to monolithic two-wavelength semiconductor laser element 310 having red and infrared semiconductor laser elements 50 and 70 integrally formed into a single body, unlike the first embodiment.

As shown in FIG. 14, in three-wavelength semiconductor laser device 300 according to the third embodiment, monolithic two-wavelength semiconductor laser element 310, which includes red and infrared semiconductor laser elements 50 and 70 formed on a lower surface of n-type GaAs substrate 311 at a predetermined interval (approximately 30 μm, for example) in the B direction, is bonded to the upper surface of blue-violet semiconductor laser element 10 with conductive bonding layer 1 interposed therebetween. Monolithic two-wavelength laser element 310 is an example of the “second semiconductor laser element” of the invention.

Herein, in the third embodiment, as shown in FIG. 14, at both ends of monolithic two-wavelength semiconductor laser element 310 in the B direction, recesses 310b and 310c are formed individually. Recess 310b has an end face different from cavity facet 50a of red semiconductor laser element 50, while recess 310c has an end face different from cavity facet 70a of infrared semiconductor laser element 70. Recesses 310b and 310c extend in the C1 direction through all the semiconductor layers between the upper and lower surfaces of monolithic two-wavelength semiconductor laser element 310. Herein, recesses 310b and 310c are examples of the “second recess” of the invention. The upper surface and lower surface of monolithic two-wavelength semiconductor laser element 310 are examples of “second surface” and “third surface” of the invention, respectively.

In the third embodiment, recess 10b of blue-violet semiconductor laser element 10 and recess 310b of monolithic two-wavelength semiconductor laser element 310 extend from substantially the same position in the B1 direction toward an end of three-wavelength semiconductor laser device 300 (in B1 direction). Recess 10b of blue-violet semiconductor laser elements 10 and recess 310c of monolithic two-wavelength semiconductor laser element 310 extend from substantially the same position in the B2 direction toward an end of three-wavelength semiconductor laser device 300 (in B2 direction). In three-wavelength semiconductor laser device 300, therefore, continuous recesses extending substantially linearly in the C1 direction from the upper surface of monolithic two-wavelength semiconductor laser element 310 into n-type GaN substrate 11 are individually formed at both ends of cavity facet 10a of blue-violet semiconductor laser element 10 in the B direction.

As shown in FIG. 14, in monolithic two-wavelength semiconductor laser element 310, red and infrared semiconductor elements 50 and 70 are formed on the lower surface of n-type GaAs substrate 311 at a predetermined interval (approximately 30 μm, for example) in the B direction. Thus, monolithic two-wavelength semiconductor laser element 310 is positioned over the region where ridge 15 of blue-violet semiconductor laser element 10 is formed, and is bonded to both sides of the ridge 15 of blue-violet semiconductor laser element 10. On the upper surface of n-type GaAs substrate 311, n-side electrode 312 including Ti, Pt, and Au layers is formed.

Monolithic two-wavelength semiconductor laser element 310 is electrically connected to base 90 (see FIG. 2) through metallic wire 36, which is wire-bonded to n-side electrode 312. Note that, the other part of the structure of three-wavelength semiconductor laser device 300 according to the third embodiment is the same as that of the aforementioned first embodiment.

Next, with reference to FIGS. 3, 14, and 15, a description is given of a manufacturing process of three-wavelength semiconductor laser device 300 according to the third embodiment.

First, using the manufacturing process the same as that of the first embodiment, a wafer including blue-violet semiconductor laser element 10 (see FIG. 3) except for n-side electrode 18 is formed. Next, as shown in FIG. 15, on the upper surface of n-type GaAs substrate 311, n-type cladding layer 72, active layer 73, and p-type cladding layer 74, which constitute infrared semiconductor laser elements 70, are formed sequentially. N-type cladding layer 72, active layer 73, and p-type cladding layer 74 are then partially etched to expose portions of the upper surface of n-type GaAs substrate 311. On a part of each exposed portion, n-type cladding layer 52, active layer 53, and p-type cladding layer 54, which constitute red semiconductor laser element 50, are formed sequentially. Subsequently, ridges 55 and 75 are formed by etching, and current block layers 56 and 76 are formed on the upper surfaces of p-type cladding layers 54 and 74 except for ridges 55 and 75, respectively. After that, on the upper surfaces of ridges 55 (75) and current block layers 56 (76), p-side pad electrodes 57 (77) are formed, respectively.

Thereafter, as shown in FIG. 15, etching is used to remove predetermined regions between p-type cladding layer 54 (74) and n-type GaAs substrate 311, thus forming recesses 311b and separating grooves 311c whose bottoms reach to n-type GaAs substrate 311. In such a way, a wafer including monolithic two-wavelength semiconductor laser elements 310 except for n-side electrodes 312 is formed.

Electrode layers 21 (22) provided for the wafer including blue-violet semiconductor laser element 10 (see FIG. 3) and p-side pad electrodes 57 (77) formed in the wafer including monolithic two-wavelength semiconductor laser elements 310 (see FIG. 15) are placed opposite to each other, and are bonded using conductive bonding layer 1. After that, the upper surface of n-type GaAs substrate 311 is etched so that n-type GaAs substrate 311 has about 100 μm thickness. On the upper surface of n-type GaAs substrate 311, n-side electrode 312 is then formed by vacuum deposition. Moreover, after the lower surface of n-type GaN substrate 11 is ground, n-side electrode 18 is formed on the lower surface of n-type GaN substrate 11.

Note that, the other part of the manufacturing process of the third embodiment is the same as that of the aforementioned first embodiment. In such a manner, three-wavelength semiconductor laser device 300 according to the third embodiment (see FIG. 14) is formed.

In the third embodiment, as described above, red semiconductor laser element 50 and infrared semiconductor laser element 70 are formed on the surface of n-type GaAs substrate 311, so that n-side electrode 312 which is on the opposite side to p-side pad electrode 57 of red semiconductor laser element 50 and p-side pad electrode 77 of infrared semiconductor laser element 70 can be commonly provided on the rear surface of n-type GaAs substrate 311 (on the upper side in FIG. 14). Note that, the other effects of the third embodiment are the same as those of the first embodiment.

### First Modification of Third Embodiment

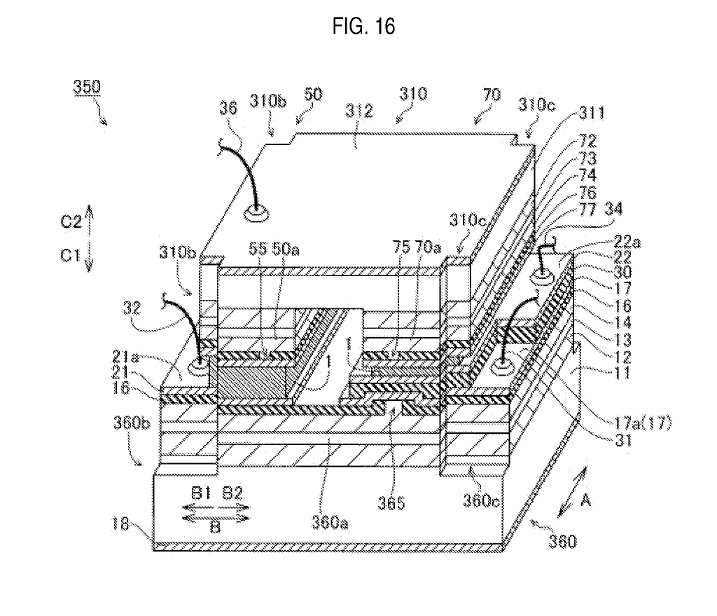

FIG. 16 is a perspective view showing a structure of a three-wavelength semiconductor laser device according to a first modification of the third embodiment. In the first modification of the third embodiment, with reference to FIG. 16, a description is given of a case where three-wavelength semiconductor laser device 350 is formed by bonding monolithic two-wavelength semiconductor laser element 310 to the upper surface of blue-violet semiconductor laser element 360 so that ridge 365 of blue-violet semiconductor laser element 360 and ridge 75 of infrared semiconductor laser element 70 are at substantially the same position in the B direction, unlike the third embodiment. Note that, blue-violet semiconductor laser element 360 is an example of the “first semiconductor laser element” of the invention. The upper surface of blue-violet semiconductor laser element 360 is an example of the “first surface” of the invention.

As shown in FIG. 16, in the first modification of the third embodiment, at both ends of cavity facet 360a of blue violet semiconductor laser element 360 in the B direction, recesses 360b and 360c which have end faces different from cavity facet 360a are formed individually. Bottoms of recess 360b and 360c reach into n-type GaN substrate 11. Herein, cavity facet 350a is an example of the “first cavity facet” of the invention, and recesses 360b and 360c are examples of the “first recess” of the invention.

Recess 360b of blue-violet semiconductor laser element 360 and recess 310b of monolithic two-wavelength semiconductor laser element 310 extend starting from substantially the same position in the B1 direction toward an end of three-wavelength semiconductor laser device 350 (in B1 direction). Recess 360c of blue-violet semiconductor laser element 360 and recess 310c of monolithic two-wavelength semiconductor laser element 310 extend starting from substantially the same position in the B2 direction toward an end of three-wavelength semiconductor laser device 350 (in B2 direction). In three-wavelength semiconductor laser device 350, therefore, continuous recesses extending substantially linearly in the C1 direction from the upper surface of monolithic two-wavelength semiconductor laser element 310 into n-type GaN substrate 11 formed at both ends of cavity facet 360a.

As shown in FIG. 16, in three-wavelength semiconductor laser device 350, ridge 365 is formed at a position a predetermined distance (approximately 50 μm, for example) away in the B2 direction from substantially the center of the element in the B direction in blue-violet semiconductor laser element 360. The three-wavelength semiconductor laser device 350 is therefore bonded to blue-violet semiconductor laser element 360 so that ridge 365 and ridge 75 of infrared semiconductor laser element 70 are positioned at substantially the same position in the B direction.

Note that, the other parts of the structure and manufacturing process of three-wavelength semiconductor laser device 350 according to the first modification of the third embodiment are the same as those of the aforementioned third embodiment. The other effects of the first modification of the third embodiment are the same as those of the above third embodiment.

### Second Modification of Third Embodiment

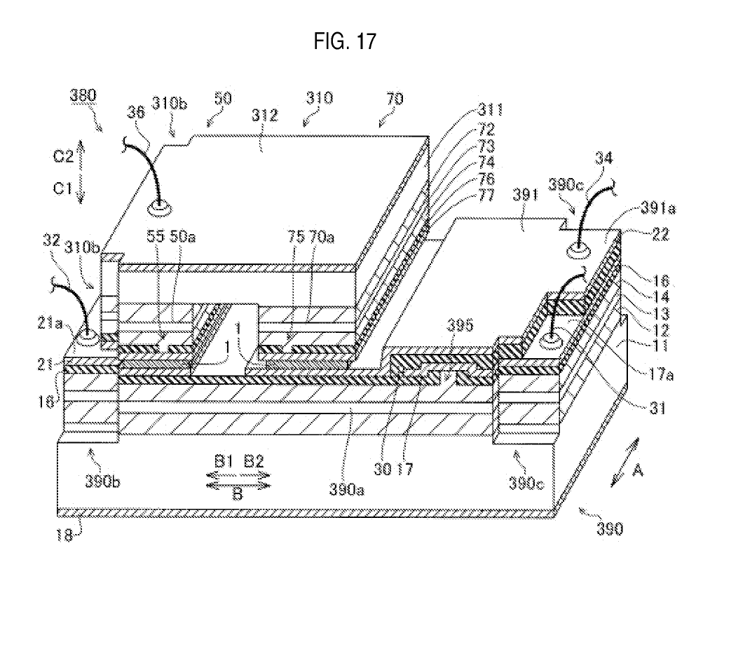

FIG. 17 is a perspective view showing a structure of a three-wavelength semiconductor laser device according to a second modification of the third embodiment. In the second modification of the third embodiment, with reference to FIG. 17, a description is given of a case where three-wavelength semiconductor laser device 380 is formed by bonding monolithic two-wavelength semiconductor laser element 310 so as not to be positioned over ridge 395 of blue-violet semiconductor laser element 390 in B direction, unlike the third embodiment. Blue-violet semiconductor laser element 390 is an example of the “first semiconductor laser element” of the invention.

As shown in FIG. 17, in the second modification of the third embodiment, at both ends of cavity facet 390a of blue violet semiconductor laser element 390 in the B direction, recesses 390b and 390c which have end faces different from cavity facet 390a are formed individually. Bottoms of recess 390b and 390c reach into n-type GaN substrate 11. Herein, cavity facet 390a is an example of the “first cavity facet” of the invention, and recesses 390b and 390c are examples of the “first recess” of the invention.

Recess 390b of blue-violet semiconductor laser element 390 and recess 310b of monolithic two-wavelength semiconductor laser element 310 extend starting from substantially the same position in the B1 direction toward an end of three-wavelength semiconductor laser device 380 (in B1 direction). In three-wavelength semiconductor laser device 380, therefore, a single continuous recess extending substantially linearly in the C1 direction from the upper surface of monolithic two-wavelength semiconductor laser element 310 into n-type GaN substrate 11 is formed at an end of cavity facet 390a in the B1 direction.

As shown in FIG. 17, in blue-violet semiconductor laser element 390, ridge 395 is formed at offset position in the B2 direction from substantially the center of the element in the B direction. On ridge 395, p-side pad electrode 17 extending in the B2 direction is formed. Moreover, electrode layer 391 is formed so as to cover a predetermined region of the upper surface of current block layer 16 on a side of ridge 395 in the B1 direction. Moreover, electrode layer 391 extends to an end region of blue-violet semiconductor laser element 390 in the B2 direction on the insulating film 30 formed on p-side pad electrode 17.

Note that, the other parts of the structure and manufacturing process of three-wavelength semiconductor laser device 380 according to the second modification of the third embodiment are the same as those of the aforementioned third embodiment. The other effects of the second modification of the third embodiment are the same as those of the above third embodiment.

### Fourth Embodiment

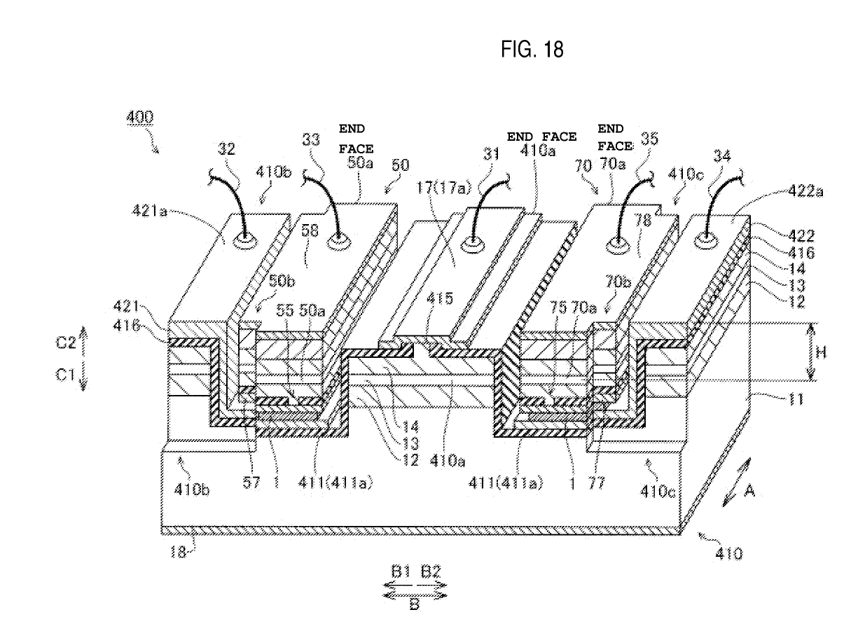

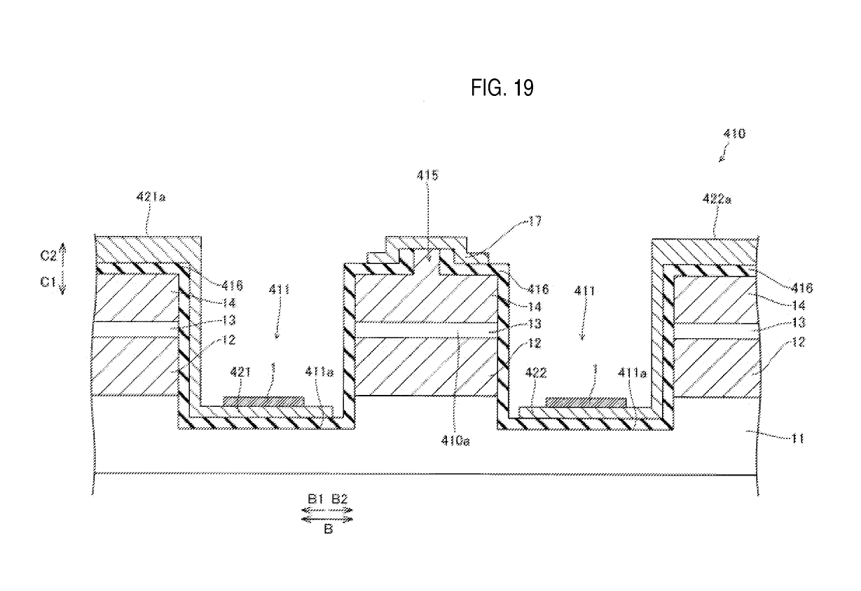

FIG. 18 is a perspective view showing a structure of a three-wavelength semiconductor laser device according to a fourth embodiment. FIG. 19 is a view illustrating a manufacturing process of the three-wavelength semiconductor laser device according to the fourth embodiment shown in FIG. 18. In this fourth embodiment, with reference to FIG. 18, a description is first given of a case where, unlike the first embodiment, three-wavelength semiconductor laser device 400 is formed by bonding red infrared semiconductor laser element 50 and infrared semiconductor laser element 70 to regions including recessed portions 411 which are on both sides of semiconductor layers including ridge 415 (an optical waveguide) of blue-violet semiconductor laser element 410. Note that, blue-violet semiconductor laser element 410 is an example of the “first semiconductor laser element” of the invention.

As shown in FIG. 18, in three-wavelength semiconductor laser device 400 according to the fourth embodiment, red semiconductor laser elements 50 and infrared semiconductor laser element 70 are bonded to blue-violet semiconductor laser element 410 with conductive bonding layers 1 interposed therebetween.

Herein, in the fourth embodiment, as shown in FIG. 18, blue-violet semiconductor laser element 410 includes recessed portions 411 which are formed on both sides of semiconductor layers including ridge 415 (the optical waveguide) in the B direction so as to extend in the A direction. Bottoms 411a thereof reach into n-type GaN substrate 11. Current block layer 416 is formed so as to continuously cover surfaces of recessed portions 411 and side surfaces of the semiconductor layers.

Electrode layers 421 and 422 are formed so as to cover current block layers 416 from the respective places on bottoms 411a toward both ends of blue-violet semiconductor laser element 410 in the B1 and B2 directions, respectively. At the outer ends of electrode layers 421 and 422 in the B direction, wire bonding regions 421a and 422a are formed, respectively.

As shown in FIG. 18, p-side pad electrode 57 of red semiconductor laser element 50 is bonded to a part of electrode layer 421 on recessed portion 411 of blue-violet semiconductor laser element 410 with conductive bonding layer 1 interposed therebetween. P-side pad electrode 77 of infrared semiconductor laser element 70 is bonded to a part of electrode layer 422 on recessed portion 411 of blue-violet semiconductor laser element 410 with conductive bonding layer 1 interposed therebetween.

In the fourth embodiment, as shown in FIG. 18, at both ends of n-type GaN substrate 11 of blue-violet semiconductor laser element 410 in the B direction, recesses 410b and 410c having end faces different from cavity facet 410a are respectively formed. The bottoms of recesses 410b and 410c reach into n-type GaN substrate 11. Note that, cavity facet 410a is an example of the “first cavity facet” of the invention, and recesses 410b and 410c are examples of the “first recess” of the invention.

In the fourth embodiment, as shown in FIG. 18, recesses 410b and 50b extend starting from substantially the same position in the B1 direction toward an end of three-wavelength semiconductor laser device 400 (in B1 direction). Recesses 410c and 70b extend starting from substantially the same position in the B2 direction toward an end of three-wavelength semiconductor laser device 400 (in B2 direction). In three-wavelength semiconductor laser device 400, therefore, continuous recesses extending substantially linearly in the C1 direction from the upper surfaces of red and infrared semiconductor laser elements 50 and 70 into n-type GaN substrate 11 are respectively formed at both ends of cavity facet 410a (n-type GaN substrate 11) in the B direction. Note that, the other part of the structure of three-wavelength semiconductor laser device 400 according to the fourth embodiment is the same as that of the first embodiment.

Next, with reference to FIGS. 18 and 19, a description is given of a manufacturing process of three-wavelength semiconductor laser device 400 according to the fourth embodiment.

First, by the same manufacturing process as the first embodiment, a wafer including blue-violet semiconductor laser elements 410 is formed. At this time, as shown in FIG. 19, after ridge 415 is formed in p-type cladding layer 14, the semiconductor layers of the sides of ridge 415 are etched to leave ridge 415 and region in the vicinity of the ridge 415, so that recessed portions 411 are formed extending in the A direction (see FIG. 18). Current block layers 416 are then formed on bottoms 411a of recessed portions 411 and side surfaces of the semiconductor layers except for ridges 415.

As shown in FIG. 19, electrode layers 421 and 422 are formed by vacuum deposition so as to cover regions except protruding section with ridge 415 of current block layers 416. At this time, in the fourth embodiment, electrode layer 421 extends, from a portion of current block layers 416 within a part of blue-violet semiconductor laser element 410 which is bonded to red semiconductor laser element 50, to the end of blue-violet semiconductor laser element 410 in the B1 direction through the side surface of recessed portion 411. Electrode layer 421 includes wire bonding region 421a at the end in the B1 direction. Electrode layer 422 extends, from a portion of current block layer 416 within a part of blue-violet semiconductor laser element 410 which is bonded to infrared semiconductor laser element 70, to the end of blue-violet semiconductor laser element 410 in the B2 direction through the side surface of recessed portion 411. Electrode layer 421 includes wire bonding region 422a at the end in the B2 direction.

Moreover, using the same manufacturing process as that of the first embodiment, electrode layers 421 and 422 provided for the wafer including the blue-violet semiconductor laser element 410 except for n-side electrode 18 and the wafer including red semiconductor laser element 50 and infrared semiconductor laser element 70 formed on GaAs substrate 60 are placed opposite to each other, and are bonded with conductive bonding layer 1 interposed therebetween.

Note that, the other part of the manufacturing process of the fourth embodiment is the same as that of the first embodiment. In such a manner, three-wavelength semiconductor laser device 400 according to the fourth embodiment (see FIG. 18) is fabricated.

In the fourth embodiment, as described above, active layer 53 of red semiconductor laser element 50, active layer 73 of infrared semiconductor laser element 70, and active layer 13 of blue-violet semiconductor laser element 410 are arranged in substantially the same plane (at substantially the same distance H from the upper surface of three-wavelength semiconductor laser device 400 in the thickness direction of the semiconductor layers (in C1 direction in FIG. 18)) at predetermined intervals in B direction. Accordingly, light emitting regions of semiconductor laser elements (50, 70, and 410) can be arranged in substantially the same plane, and light beams emitted from the semiconductor laser elements (50, 70, and 410) can be aligned in substantially the same line. If three-wavelength semiconductor laser device 400 is applied to optical disk pick-up apparatus, therefore, designing the optical system thereof can be facilitated. The other effects of the fourth embodiment are the same as those of the aforementioned first embodiment.

### First Modification of Fourth Embodiment

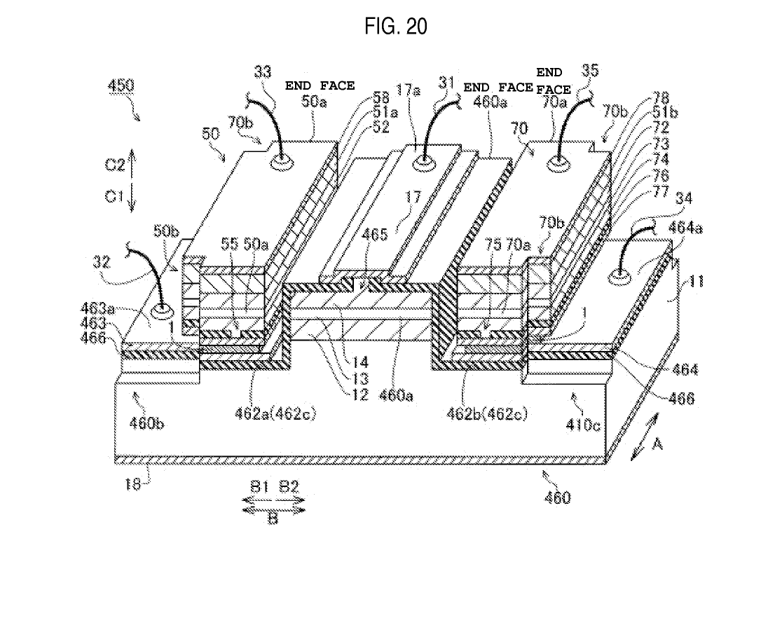

FIG. 20 is a perspective view showing a structure of a three-wavelength semiconductor laser device according to a first modification of the fourth embodiment. In this first modification of the fourth embodiment, with reference to FIG. 20, a description is given of a case where, unlike the manufacturing process of the fourth embodiment, three-wavelength semiconductor laser device 450 is fabricated by forming recesses 462a and 462b on both sides of the semiconductor layers of blue-violet semiconductor laser element 460 including ridge 465 (an optical waveguide), and then bonding red and infrared semiconductor laser elements 50 and 70 to recessed portions 462a and 462b, respectively. Herein, bottoms of recessed portions 462a and 462b reach into n-type GaN substrate 11.

In the first modification of the fourth embodiment, as shown in FIG. 20, on both sides of the semiconductor layers of blue-violet semiconductor laser element 460 including ridge 465 (an optical waveguide), recessed portions 462a and 462b are respectively formed. Bottoms 462c thereof reach into n-type GaN substrate 11. Current block layers 466 are formed so as to cover the surfaces of recessed portions 462a and 462b and the side surfaces of the semiconductor layers.

On a portion of current block layers 466 corresponding to bottom 462c of recessed portion 462a, electrode layer 463 extending toward an end of n-type GaN substrate 11 in the B1 direction is formed. On a portion of current block layers 466 corresponding to bottom 462c of recessed portion 462b, electrode layer 464 extending toward an end of n-type GaN substrate 11 in the B2 direction is formed.

Note that, the other parts of the structure and manufacturing process of the first modification of the fourth embodiment are the same as those of the fourth embodiment. The effects of the first modification of the fourth embodiment are the same as those of the fourth embodiment.

### Second Modification of Fourth Embodiment

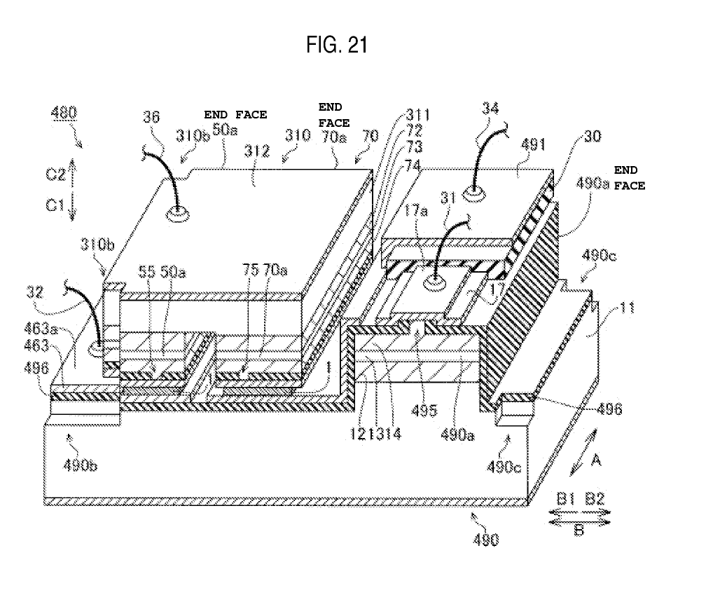

FIG. 21 is a perspective view showing a structure of a three-wavelength semiconductor laser device according to a second modification of the fourth embodiment. In this second modification of the fourth embodiment, with reference to FIG. 21, a description is given of a case where, unlike the first modification of the fourth embodiment, three-wavelength semiconductor laser device 480 is formed by bonding monolithic two-wavelength semiconductor laser element 310 so as not to be positioned over ridge 495 of blue-violet semiconductor laser element 490 in the B direction. Note that, blue-violet semiconductor laser element 490 is an example of the “first semiconductor laser element” of the invention.

In the second modification of the fourth embodiment, as shown in FIG. 21, recesses 490b and 490c having end faces different from cavity facet 490aare formed at both ends of cavity facet 490a of blue-violet semiconductor laser element 490 in B direction. Bottoms of recesses 490b and 490c reach into n-type GaN substrate 11. Note that, cavity facet 490a is an example of the first cavity facet of the invention, and recesses 490b and 490c are examples of the “first recess” of the invention.

Recesses 490b and 310b of blue-violet and monolithic two-wavelength semiconductor laser elements 490 and 310 extend starting from substantially the same position in the B1 direction toward an end of three-wavelength semiconductor laser device 480 (in B1 direction). In three-wavelength semiconductor laser device 480, therefore, a single continuous recess extending substantially linearly in the C1 direction from the upper surface of monolithic two-wavelength semiconductor laser element 310 into n-type GaN substrate 11 is formed at an end of cavity facet 490a in the B1 direction.

As shown in FIG. 21, in blue-violet semiconductor laser element 490, semiconductor layers including ridge 495 are formed at a position a predetermined distance (approximately 50 μm, for example )away in the B2 direction from substantially the center of the element in the B direction, and on ridge 495, p-side pad electrode 17 extending in the A direction is formed. Moreover, electrode layer 491 covers a part of upper portion of protrude section of the upper surface of current block layers 496. Electrode layer 491 also covers a region on current block layers 496, which is from substantially center of recess between semiconductor laser elements of monolithic two-wavelength semiconductor laser elements 310 to the side surface of ridge 495 in the B1 direction from ridge 495. Furthermore, electrode layer 491 covers a part of region of p-side electrode 17 with insulating film 30 interposed therebetween, the insulating film 30 being formed on p-side pad electrode 17.

Note that, the other parts of the structure and manufacturing process of three-wavelength semiconductor laser device 480 according to a second modification of the fourth embodiment are the same as those of the third and fourth embodiments. The effects of the second modification of the fourth embodiment are the same as those of the fourth embodiment.

### Fifth Embodiment

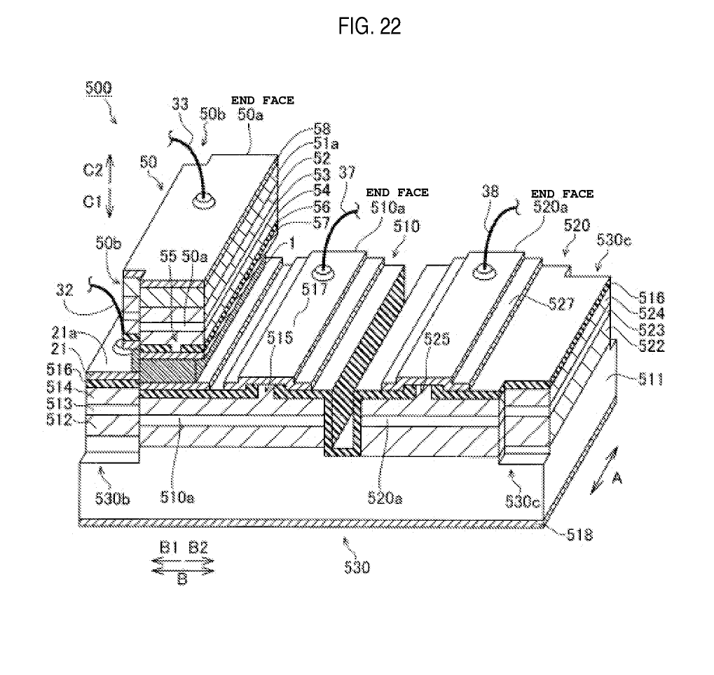

FIG. 22 is a perspective view showing a structure of an RGB three-wavelength semiconductor laser device according to a fifth embodiment. In the fifth embodiment, with reference to FIG. 22, a description is given of a case where, unlike the first to fourth embodiments, RGB three-wavelength semiconductor laser device 500 is formed by bonding red semiconductor laser element 50 to the upper surface of monolithic two-wavelength semiconductor laser element 530 including green and blue semiconductor laser elements 510 and 520. Monolithic two-wavelength semiconductor laser element 530 is an example of the “first semiconductor laser element” of the invention. The upper surface of monolithic two-wavelength semiconductor laser element 530 is an example of the “first surface” of the invention.

As shown in FIG. 22, in RGB three-wavelength semiconductor laser device 500 according to the fifth embodiment, red semiconductor laser element 50 is bonded to monolithic two-wavelength semiconductor laser element 530 with conductive bonding layer 1 interposed therebetween.

In the fifth embodiment, as shown in FIG. 22, at both ends of monolithic two-wavelength semiconductor laser element 530 in the B direction, recess 530b having an end face different from cavity facet 510a of green semiconductor laser element 510 and recess 530c having an end face different from cavity facet 520a of blue semiconductor laser element 520 are respectively formed. Bottoms of recesses 530b and 530c reach into n-type GaN substrate 511. Note that, cavity facets 510a and 520a are examples of the “first cavity facet” of the invention, and n-type GaN substrate 511 is an example of a “substrate” of the invention. Recesses 530b and 530c are examples of the “first recess” of the invention.

In the fifth embodiment, recess 50b formed at an end of cavity facet 50a of red semiconductor laser element 50 in the B1 direction extends in the C1 direction through all the semiconductor layers between upper and lower surfaces of red semiconductor laser element 50. Recesses 530b and 50b are formed so as to extend starting from substantially the same position in the B1 direction toward an end of RGB three-wavelength semiconductor laser device 500 (in B1 direction). In RGB three-wavelength semiconductor laser device 500, therefore, a continuous recess extending substantially linearly in the C1 direction from the upper surface of red semiconductor laser element 50 into n-type GaN substrate is formed at the end of cavity facet 510a in the B1 direction.

As shown in FIG. 22, green semiconductor laser element 510 includes: n-type cladding layer 512 made of n-type AlGaN; active layer 513; and p-type cladding layer 514 made of p-type AlGaN, which are formed on the upper surface of n-type GaN substrate 511. Blue semiconductor laser element 520 includes: n-type cladding layer 522 made of n-type AlGaN; active layer 523; and p-type cladding layer 524 made of p-type AlGaN, which are formed on the upper surface of n-type GaN substrate 511.

Current block layers 516 made of SiO₂ are formed so as to cover upper surfaces of flat sections of p-type cladding layer 514 and side surfaces of ridge section 515 in green semiconductor laser element 510, and to cover upper surfaces of flat sections of p-type cladding layer 524 and side surfaces of ridge 525 in blue semiconductor laser element 520. Moreover, p-side pad electrode 517 is formed so as to cover upper surfaces of ridge 515 and corresponding part of current block layers 516. P-side pad electrode 527 is formed so as to cover upper surfaces of ridge 525 and corresponding part of current block layers 516.

As shown in FIG. 22, green semiconductor laser element 510 is connected to a lead terminal (not shown) through metallic wire 37, which is wire-bonded to p-side pad electrode 517. Blue semiconductor laser element 520 is connected to a lead terminal (not shown) through metallic wire 38, which is wire-bonded to p-side pad electrode 527. N-side electrode 518 of monolithic two-wavelength semiconductor laser element 530 is electrically connected to base 90 (see FIG. 2) through conductive bonding layer (not shown). RGB three-wavelength semiconductor laser device 500 therefore has a configuration in which the p-side electrodes of the semiconductor laser elements are connected to the lead terminals insulated from each other while n-side electrodes are connected to a common terminal (cathode common configuration).

Note that, the other parts of the structure and manufacturing process of RGB three-wavelength semiconductor laser device 500 according to the fifth embodiment are the same as those of the first embodiment. The effects of the fifth embodiment are the same as those of the first embodiment.

For example, the first embodiment shows the example in which the three-wavelength semiconductor laser device is formed by bonding red and infrared semiconductor laser elements to blue-violet semiconductor laser element including GaN compound semiconductors stacked on the n-type GaN substrate. However, the invention is not limited to this and may include an RGB three-wavelength semiconductor laser device formed by bonding blue and red semiconductor laser elements on the upper surface of a green semiconductor laser element formed on a GaN substrate.

Moreover, the first embodiment shows the example of the three-wavelength laser element by bonding red and infrared semiconductor laser elements to the blue-violet semiconductor laser element including the GaN compound semiconductors stacked on the n-type GaN substrate. However, the invention is not limited to this and may include an RGB three-wavelength semiconductor laser device formed by bonding green and red semiconductor laser elements to the upper surface of a blue semiconductor laser element formed on a GaN substrate.

The fourth embodiment shows an example in which the three-wavelength laser semiconductor element is formed by bonding red and infrared semiconductor laser elements so as to correspond to the recessed portions formed on both sides of blue-violet semiconductor laser element. However, the invention is not limited to this and may include an RGB three-wavelength semiconductor laser device formed by bonding blue and green semiconductor laser elements so as to correspond to the recessed portions formed on both sides of a red semiconductor laser element formed on a GaAs substrate.

The first to fifth embodiments show the examples in which the blue-violet semiconductor laser element is made of nitride semiconductor layers made of AlGaN, InGaN, and the like. However, the invention is not limited to this, and the blue-violet semiconductor laser element may be made of nitride semiconductor layers of a wurtzite structure which is made of AlN, InN, BN, TlN, and mixed crystal thereof.

The semiconductor laser device may be formed by bonding a blue-violet semiconductor laser element wafer including a layer with nitride compound semiconductors on the GaN substrate to a monolithic red/infrared semiconductor laser element(s) wafer including compound such as gallium and phosphor on a GaN substrate, and then cavity facets may be formed by cleaving the bonded wafers.

As described above, according to the semiconductor laser device of the embodiments and the manufacturing methods thereof, in an integrated multi-wavelength semiconductor laser device, it is possible to prevent cavity facets constituting the semiconductor laser elements from being misaligned in the cavity direction.

The invention includes other embodiments in addition to the above-described embodiments without departing from the spirit of the invention. The embodiments are to be considered in all respects as illustrative, and not restrictive. All configurations including the meaning and range within equivalent arrangements of the claims are intended to be embraced in the invention.

What is claimed is:

1. A semiconductor laser device comprising:
a first semiconductor laser element which is formed on a surface of a substrate and has a first cavity facet, the first semiconductor laser element having a first recess in a region of the first cavity facet except for at least a region where a first optical waveguide is formed, the first recess extending in a first direction in which the first cavity facet extends; and
a second semiconductor laser element which is bonded to a first surface of the first semiconductor laser element, the first surface being opposite side of the first laser element to the substrate, and has a second cavity facet formed in substantially the same plane as the first cavity facet, the second semiconductor laser element having a second recess in a region of the second cavity facet except for at least a region where a second optical waveguide is formed, the second recess extending in a second direction in which the second cavity facet extends.

2. The semiconductor laser device of claim 1, wherein the second recess extends from a second surface of the second semiconductor laser element to a third surface of the second semiconductor laser element, the second surface opposite side of the second laser element to the first semiconductor laser element, the third surface being bonded to the first semiconductor laser element.

3. The semiconductor laser device of claim 2, wherein the first recess is formed to extend from the first surface to the substrate so as to be continuous with the second recess extending from the second surface to the third surface.

4. The semiconductor laser device of claim 1, wherein formation regions of the respective first and second recesses are arranged so as to overlap with each other in a plan view.

5. The semiconductor laser device of claim 1, wherein
the first recess is formed in a vicinity of a first end of the first cavity facet, in the first direction, and
the second recess is formed in a vicinity of a second end of the second cavity facet, in the second direction, the second end being on the same side where the first recess is formed.

6. The semiconductor laser device of claim 1, wherein the first semiconductor laser element lases different lasing wavelength with the second semiconductor laser element.

7. The semiconductor laser device of claim 1, wherein at least one of the first semiconductor laser element and the second semiconductor laser element is a nitride semiconductor laser device.

8. The semiconductor laser device of claim 1, wherein at least one of the first semiconductor laser element and the second semiconductor laser element is an arsenic semiconductor laser device.

9. The semiconductor laser device of claim 1, wherein at least one of the first semiconductor laser element and the second semiconductor laser element is a phosphorus semiconductor laser device.

10. The semiconductor laser device of claim 1, wherein the width of the first semiconductor laser element is wider than that of the second semiconductor laser element.

11. The semiconductor laser device of claim 1, wherein the second optical waveguide is arranged at a position offset to the first optical waveguide from substantially a center of the second semiconductor laser element in the second direction.

12. The semiconductor laser device of claim 1, wherein the first optical waveguide and the second optical waveguide are aligned in substantially the same line in the first direction.

13. The semiconductor laser device of claim 1, wherein the lengths of resonating of the first semiconductor laser element are the substantially same as that of the second semiconductor laser element.

14. The semiconductor laser device of claim 1, wherein the first recess is arranged both end of the first semiconductor laser element in the first direction, and not arranged other end of the first semiconductor laser element in the first direction.

15. The semiconductor laser device of claim 1, wherein the first recess is arranged one end of the first semiconductor laser element in the first direction, and not arranged other end of the first semiconductor laser element in the first direction.

16. The semiconductor laser device of claim 1, further comprising a third recess extending in parallel to the first optical waveguide in the first surface, and the second semiconductor laser device is bonded at a bottom surface of the third recess.

17. The semiconductor laser device of claim 16, wherein the first recess is arranged in the bottom surface of the third recess.

18. A manufacturing method of a semiconductor laser device comprising:
forming a first semiconductor laser element on a surface of a substrate, the first semiconductor laser element including a first optical waveguide;
forming a second semiconductor laser element including a second optical waveguide;
bonding the second semiconductor laser element to a surface of the first semiconductor laser element, the surface opposite side of the second laser element to the substrate;
forming a groove in a first region of the first semiconductor laser element and in a second region of the second semiconductor laser element, except for at least a third region where the first optical waveguide is formed and a fourth region where the second optical waveguide is formed, the groove extending in a direction substantially perpendicular to a direction in which the first and second optical waveguides extend; and
performing cleavage along the groove so as to form: the first semiconductor laser element having a first cavity facet and a first recess corresponding to the groove in the first region except for at least the third region, the first recess extending in a direction in which the first cavity facet extends; and the second semiconductor laser element having a second cavity facet and a second recess corresponding to the groove in the second region except for at least the fourth region, the second recess extending in a direction in which the second cavity facet extends.

19. The method of claim 18, further comprising:
dividing the first semiconductor laser element in the position crossing the groove after performing cleavage.

20. A manufacturing method of a semiconductor laser device comprising:
forming a first semiconductor laser element on a surface of a substrate, the first semiconductor laser element including a first optical waveguide;
forming a recess except regions in the vicinity of the first optical waveguide, the recess formed in parallel to the first optical waveguide;
forming a second semiconductor laser element including a second optical waveguide;
bonding the second optical waveguide to a bottom of the recess;
forming a groove in a first region of the first semiconductor laser element and in a second region of the second semiconductor laser element, except for at least a third region where the first optical waveguide is formed and a fourth region where the second optical waveguide is formed, the groove extending in a direction substantially perpendicular to a direction in which the first and second optical waveguides extend; and
performing cleavage along the groove so as to form: the first semiconductor laser element having a first cavity facet and a first recess corresponding to the groove in the first region except for at least the third region, the first recess extending in a direction in which the first cavity facet extends; and the second semiconductor laser element having a second cavity facet and a second recess corresponding to the groove in the second region except for at least the fourth region, the second recess extending in a direction in which the second cavity facet extends.
